(19) United States
(12) Patent Application Publication
(10) Pub. No.: US 2022/0214616 A1
(43) Pub. Date: Jul. 7, 2022

(54) PHOTORESIST COMPOSITIONS AND PATTERN FORMATION METHODS

(71) Applicants: ROHM AND HAAS ELECTRONIC MATERIALS LLC, Marlborough, MA (US); DUPONT ELECTRONICS, INC., Wilmington, DE (US)

(72) Inventors: Joshua Kaitz, Shrewsbury, MA (US); Brian Malbrecht, London (CA); Deyan Wang, Hudson, MA (US); Michael Henry Howard, JR., Montchanin, DE (US)

(21) Appl. No.: 17/564,476

(22) Filed: Dec. 29, 2021

Related U.S. Application Data
(60) Provisional application No. 63/131,899, filed on Dec. 30, 2020.

(51) Int. Cl. G03F 7/039; C08F 20/58

(52) U.S. Cl. CPC G03F 7/039; C08F 20/58

(57) ABSTRACT

A photoresist composition, comprising a first polymer comprising a first repeating unit comprising an acid-labile group, and a second polymer comprising a repeating unit derived from one or more monomers of formula (4); a photoacid generator; and a solvent,

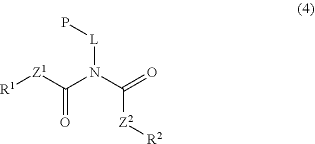

wherein Z¹, Z², R¹, R², and L are as described herein, and P is a polymerizable group.

### FIELD

The present invention relates to photoresist compositions that contain a photoactive component and a blend of two different polymers and to pattern formation methods using such photoresist compositions. The invention is germane to lithographic applications in the semiconductor manufacturing industry.

### BACKGROUND

Photoresist materials are photosensitive compositions typically used for transferring an image to one or more underlying layers such as a metal, semiconductor or dielectric layer disposed on a semiconductor substrate. To increase the integration density of semiconductor devices and allow for the formation of structures having dimensions in the nanometer range, photoresists and photolithography processing tools having high-resolution capabilities have been and continue to be developed.

Positive-tone chemically amplified photoresists are conventionally used for high-resolution processing. Such resists typically employ a polymer having acid-labile groups along with a photoacid generator. Pattern-wise exposure to activating radiation through a photomask causes the acid generator to form an acid which, during post-exposure baking, causes cleavage of the acid-labile groups in exposed regions of the polymer. This creates a difference in solubility characteristics between exposed and unexposed regions of the resist in a developer solution. In a positive tone development (PTD) process, exposed regions of the photoresist layer become soluble in the developer and are removed from the substrate surface, whereas unexposed regions, which are insoluble in the developer, remain after development to form a positive image. The resulting relief image permits selective processing of the substrate. See, e.g., Uzodinma Okoroanyanwu, Chemistry and Lithography, SPIE Press and John Wiley and Sons, Inc., 2010 and Chris Mack, Fundamental Principles of Optical Lithography, John Wiley and Sons, Inc., 2007.

One approach to achieving nm-scale feature sizes in semiconductor devices is the use of short wavelengths of light, for example, 193 nanometers (nm) or less, during exposure of chemically amplified photoresists. To further improve lithographic performance, immersion lithography tools have been developed to effectively increase the numerical aperture (NA) of the lens of the imaging device, for example, a scanner having a KrF (248 nm) or ArF (193 nm) light source. This is accomplished by use of a high refractive index fluid, typically water, between the last surface of the imaging device and the upper surface of the semiconductor wafer. ArF immersion tools are currently pushing the boundaries of lithography to dimensions below 40 nm with the use of multiple (double or higher order) patterning.

Despite the advancement in resist technology, there is still a need for photoresist compositions that address one or more problems associated with the state of the art. In particular, there is a continuing need for photoresist compositions used in immersion lithography having increased scan speeds and fewer defects.

### SUMMARY

A photoresist composition, comprising a first polymer comprising a first repeating unit comprising an acid-labile group, and a second polymer comprising a repeating unit derived from one or more monomers of formula (4); a photoacid generator; and a solvent,

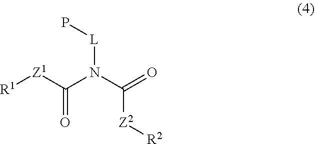

wherein, in formula (1), Z¹ and Z² are each independently a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —N(R³)—, —S—, or —S(O)₂—, wherein R³ is hydrogen, substituted or unsubstituted C₁₋₂₀ alkyl, substituted or unsubstituted C₁₋₂₀ heteroalkyl, substituted or unsubstituted C₃₋₂₀ cycloalkyl, or substituted or unsubstituted C₂₋₂₀ heterocycloalkyl, optionally, Z¹ and Z² together form a ring via a single bond or a double bond between Z¹ and Z², R¹ and R² are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, substituted or unsubstituted C₂₋₃₀ alkylheteroaryl, —OR⁴, or —N(R⁵)₂, wherein R⁴ and R⁵ are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl, optionally, R¹ and R² together form a ring via a single bond or a divalent linking group, L is a single bond or a multivalent linking group, optionally, L is a multivalent linking group further comprising an additional group of the formula:

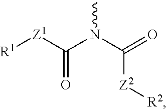

P is a polymerizable group.

Also provided is a pattern formation method, comprising (a) applying a layer of the inventive photoresist composition on a substrate; (b) pattern-wise exposing the photoresist composition layer to activating radiation; and (c) developing the exposed photoresist composition layer to provide a resist relief image.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the FIGURES, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the term “hydrocarbon group” refers to an organic compound having at least one carbon atom and at least one hydrogen atom, optionally substituted with one or more substituents where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O—”; “carboxylic acid group” refers to a group having the formula “—C(═O)—OH”; “cycloalkyl group” refers to a monovalent group having one or more saturated rings in which all ring members are carbon; “cycloalkylene group” refers to a cycloalkyl group having a valence of two; “alkenyl group” refers to a straight or branched chain, monovalent hydrocarbon group having at least one carbon-carbon double bond; “alkenoxy group” refers to “alkenyl-O—”; “alkenylene group” refers to an alkenyl group having a valence of two; “cycloalkenyl group” refers to a non-aromatic cyclic hydrocarbon group having at least three carbon atoms, with at least one carbon-carbon double bond; “alkynyl group” refers to a monovalent hydrocarbon group having at least one carbon-carbon triple bond; the term “aromatic group” refers to a monocyclic or polycyclic ring system that satisfies the Huckel Rule and includes carbon atoms in the ring, and optionally may include one or more heteroatoms selected from N, O, and S instead of a carbon atom in the ring; “aryl group” refers to a monovalent aromatic monocyclic or polycyclic ring system where every ring member is carbon, and may include a group with an aromatic ring fused to at least one cycloalkyl or heterocycloalkyl ring; “arylene group” refers to an aryl group having a valence of two; “alkylaryl group” refers to an aryl group that has been substituted with an alkyl group; “arylalkyl group” refers to an alkyl group that has been substituted with an aryl group; “aryloxy group” refers to “aryl-O—”; and “arylthio group” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl group” refers to an alkyl group having 1-4 or more heteroatoms instead of carbon; “heterocycloalkyl group” refers to a cycloalkyl group having 1-4 or more heteroatoms as ring members instead of carbon; “heterocycloalkylene group” refers to a heterocycloalkyl group having a valence of two; “heteroaryl group” refers to an aryl group having 1-4 or more heteroatoms as ring members instead of carbon; and “heteroarylene group” refers to an heteroaryl group having a valence of two.

The term “halogen” means a monovalent substituent that is fluorine (fluoro), chlorine (chloro), bromine (bromo), or iodine (iodo). The prefix “halo” means a group including one more of a fluoro, chloro, bromo, or iodo substituent instead of a hydrogen atom. A combination of halo groups (e.g., bromo and fluoro), or only a single halo group (e.g., fluoro) may be present.

“Fluorinated” shall be understood to mean having one or more fluorine atoms incorporated into the group. For example, where a C₁₋₁₈ fluoroalkyl group is indicated, the fluoroalkyl group can include one or more fluorine atoms, for example, a single fluorine atom, two fluorine atoms (e.g., as a 1,1-difluoroethyl group), three fluorine atoms (e.g., as a 2,2,2-trifluoroethyl group), or fluorine atoms at each free valence of carbon (e.g., as a perfluorinated group such as CF₃, C₂F₅, C₃F₇, or C₄F₉). A “substituted fluoroalkyl group” shall be understood to mean a fluoroalkyl group that is further substituted by an additional substituent group.

As used herein, an “acid-labile group” refers to a group in which a bond is cleaved by the catalytic action of an acid, optionally and typically with thermal treatment, resulting in a polar group, such as a carboxylic acid or alcohol group, being formed on the polymer, and optionally and typically with a moiety connected to the cleaved bond becoming disconnected from the polymer. Such acid is typically a photo-generated acid with bond cleavage occurring during post-exposure baking. Suitable acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

“Substituted” means that at least one hydrogen atom on the group is replaced with another group, provided that the designated atom's normal valence is not exceeded. When the substituent is oxo (i.e., ═O), then two hydrogens on the carbon atom are replaced. Combinations of substituents or variables are permissible. Exemplary groups that may be present on a “substituted” position include, but are not limited to, nitro (—NO₂), cyano (—CN), hydroxy (—OH), oxo (═O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof, esters (including acrylates, methacrylates, and lactones) such as C₂₋₆ alkyl esters (—C(═O)O-alkyl or —OC(═O)-alkyl) and C₇₋₁₃ aryl esters (—C(═O)O-aryl or —OC(═O)-aryl); amido (—C(═O)NR₂ wherein R is hydrogen or C₁₋₆ alkyl), carboxamido (—CH₂C(═O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₂₋₁₂ heterocycloalkyl, C₁₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group.

The present invention relates to photoresist compositions that contain a first polymer, a second polymer, a photoacid generator, a solvent, and may contain additional, optional components. The inventors have discovered that particular photoresist compositions of the invention can be used to prepare photoresist films that achieve a high contact angle during immersion scanning and that can switch polarity to become highly soluble in a basic developer such as TMAH.

The first polymer comprises a repeating unit comprising an acid-labile group, which can be cleaved by photo-generated acid at post-exposure bake conditions. The first polymer may optionally comprise a lactone group.

The first repeating unit of the first polymer may be derived from one or more monomers of formulae (1a), (1b), (1c), (1d), or (1e):

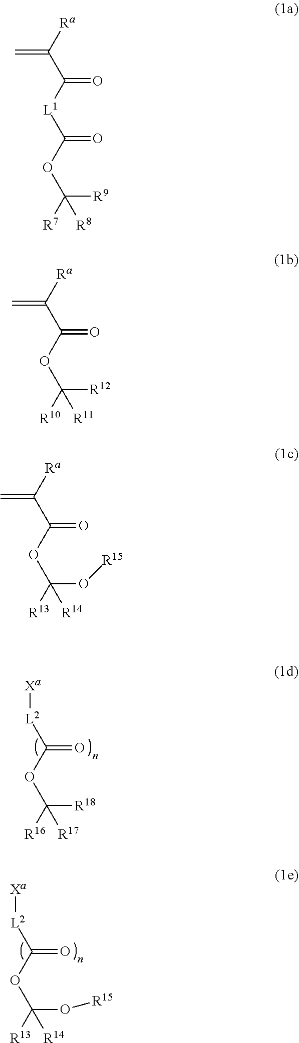

In formulae (1a) to (1e), R^{a} is hydrogen, fluorine, cyano, a substituted or unsubstituted C₁₋₁₀ alkyl, or a substituted or unsubstituted C₁₋₁₀ fluoroalkyl. Preferably, R^{a} is hydrogen, fluorine, or substituted or unsubstituted C₁₋₅ alkyl, typically methyl.

In formula (1a), L¹ is a divalent linking group including at least one carbon atom, at least one heteroatom, or a combination thereof. For example, L¹ may include 1 to 10 carbon atoms and at least one heteroatom. In a typical example, L¹ may be —OCH₂—, —OCH₂CH₂O— or —N(R^{1a})—, wherein R^{1a} is hydrogen or C₁₋₆ alkyl.

In formulae (1a) and (1b), R⁷ to R¹² are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted; provided that only one of R⁷ to R⁹ can be hydrogen and only one of R¹⁰ to R¹² can be hydrogen. Preferably, R⁷ to R¹² are each independently a straight chain or branched C₁₋₆ alkyl, or a monocyclic or polycyclic C₃₋₁₀ cycloalkyl, each of which is substituted or unsubstituted.

In formula (1a), any two of R⁷ to R⁹ together optionally may form a ring, and each of R⁷ to R⁹ optionally may further include as part of their structure one or more groups selected from —O—, —C(O)—, —C(O)—O—, —S—, —S(O)₂—, and N(R¹⁹)—S(O)₂—, wherein R¹⁹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl. In formula (1b), any two of R¹⁰ to R¹² together optionally may form a ring, and each of R¹⁰ to R¹² optionally may further include as part of their structure one or more groups selected from —O—, —C(O)—, —C(O)—O—, —S—, —S(O)₂—, and N(R²⁰)—S(O)₂—, wherein R²⁰ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl. For example, any one or more of R⁷ to R¹² can be independently a group of the formula —CH₂C(═O)CH₍₃₋ₙ₎Yₙ, where each Y is independently a substituted or unsubstituted C₂₋₁₀ heterocycloalkyl and n is 1 or 2. For example, each Y may be independently a substituted or unsubstituted C₂₋₁₀ heterocycloalkyl including a group of the formula —O(C^{a1})(C^{a2})O—, wherein C^{a1} and C^{a2} are each independently hydrogen or a substituted or unsubstituted alkyl, and where C^{a1} and C^{a2} together optionally form a ring.

In formula (1c) and (1e), R¹³ to R¹⁴ may be each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted; and R¹⁵ is straight chain or branched C₁₋₂₀ alkyl, monocyclic or polycyclic C₃₋₂₀ cycloalkyl, or monocyclic or polycyclic C₂₋₂₀ heterocycloalkyl, each of which is substituted or unsubstituted. Optionally, one of R¹³ or R¹⁴ together with R¹⁵ forms a heterocyclic ring. Preferably, R¹³ and R¹⁴ may be each independently hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

In formula (1d), R¹⁶ to R¹⁸ may be each independently straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted, any two of R¹⁶ to R¹⁸ together optionally form a ring, and each of R¹⁶ to R¹⁸ optionally may include as part of their structure one or more groups selected from —O—, —C(O)—, —C(O)—O—, —S—, —S(O)₂—, and N(R²¹)—S(O)₂—, wherein R²¹ may be hydrogen, a straight chain or branched C₁₋₂₀ alkyl, monocyclic or polycyclic C₃₋₂₀ cycloalkyl, or monocyclic or polycyclic C₂₋₂₀ heterocycloalkyl; X^{a} is a polymerizable group selected from vinyl and norbornyl.

In formulae (1d) and (1e), each L² is a single bond or a divalent linking group, provided that L² is not a single bond when X^{a} is vinyl. Preferably, L² is a monocyclic or polycyclic C₆₋₃₀ arylene or a monocyclic or polycyclic C₆₋₃₀ cycloalkylene, each of which can be substituted or unsubstituted. In formulae (1d) and (1e), n is 0 or 1. It is to be understood that when n is 0, the L² group is connected directly to the oxygen atom.

Non-limiting examples of monomers (1a) include:

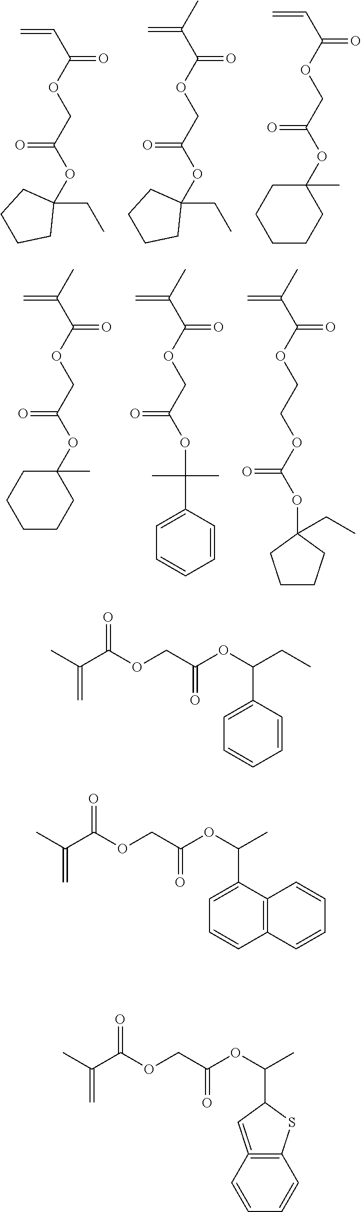

Non-limiting examples of monomers of formula (1b) include:

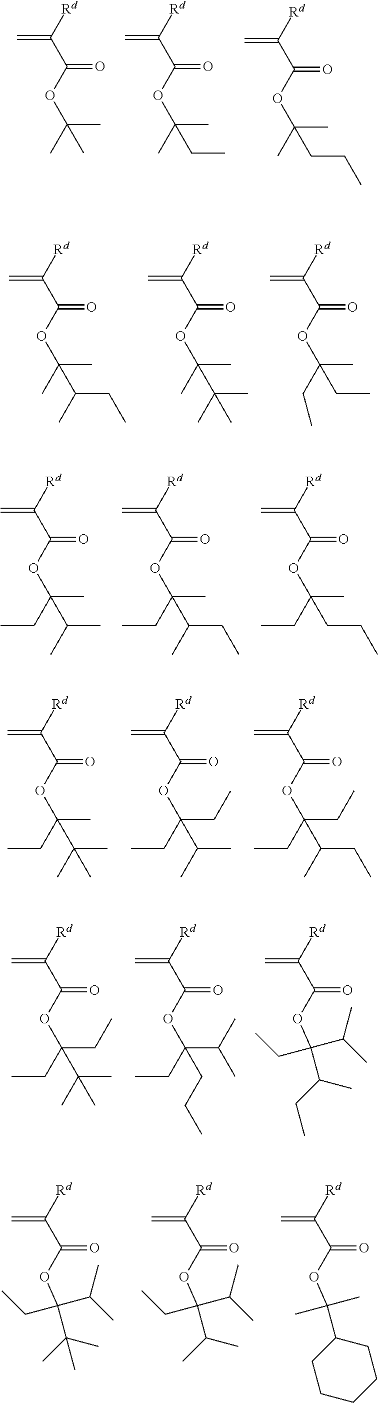

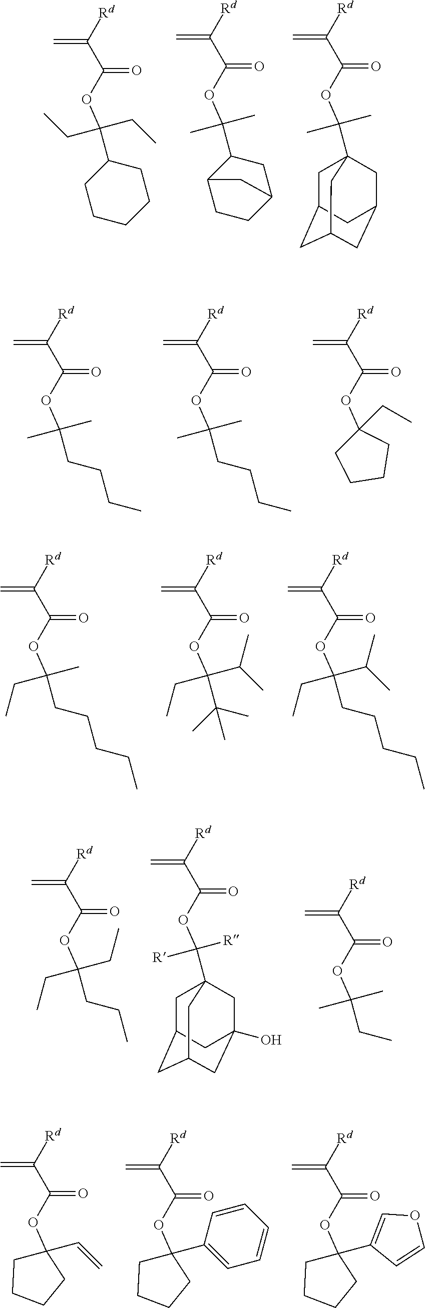

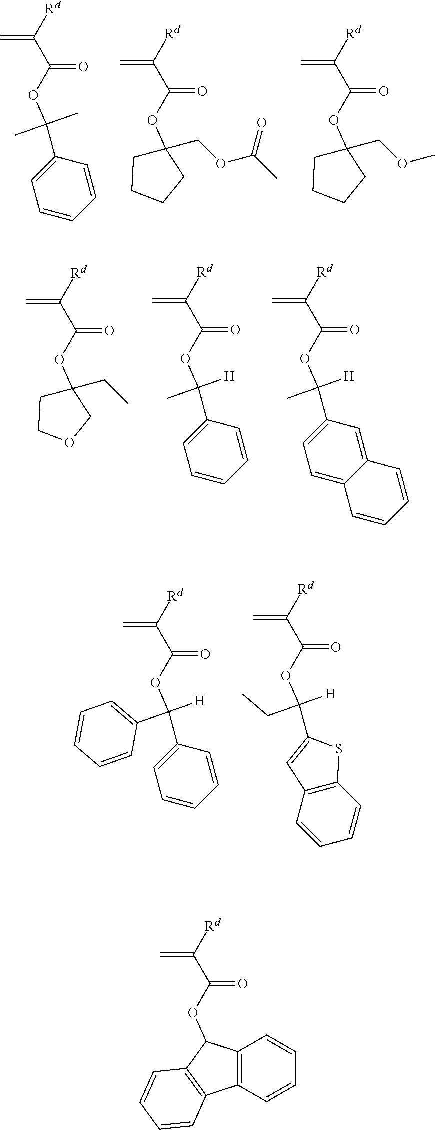

wherein R^{d} is as defined above for R^{a}; and R′ and R″ are each independently a straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted.

Non-limiting examples of monomers of formula (1c) include:

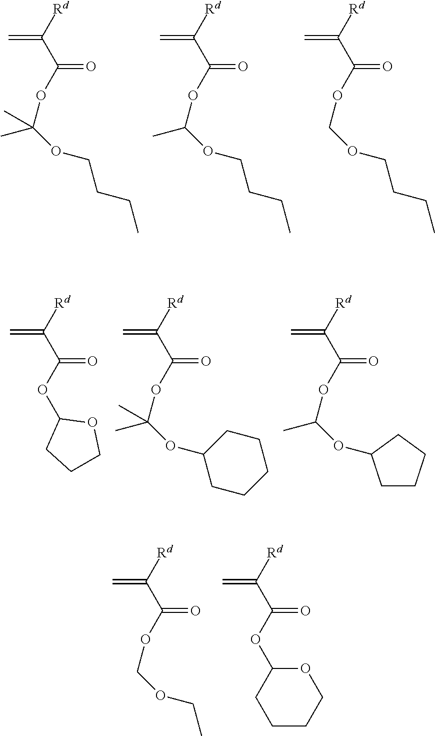

wherein R^{d} is as defined above for R^{a}.

Non-limiting examples of monomers (1d) include:

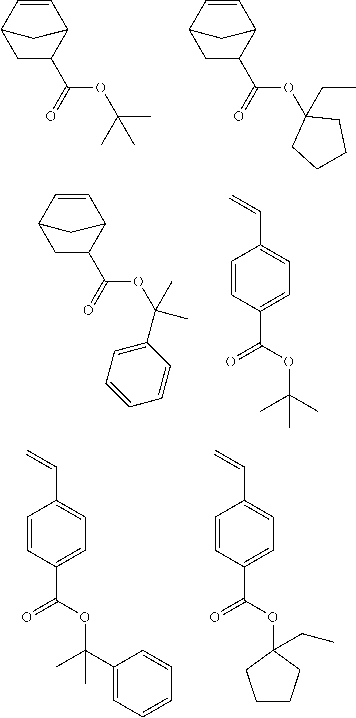 [SMILES: CC(C)(C)OC(=O)C1CC2C=CC1C2 ; CCC1(OC(=O)C2CC3C=CC2C3)CCCC1 ; CC(C)(OC(=O)C1CC2C=CC1C2)c1ccccc1 ; C=Cc1ccc(C(=O)OC(C)(C)C)cc1 ; C=Cc1ccc(C(=O)OC(C)(C)c2ccccc2)cc1 ; C=Cc1ccc(C(=O)OC2(CC)CCCC2)cc1]

Non-limiting examples of monomers (1e) include:

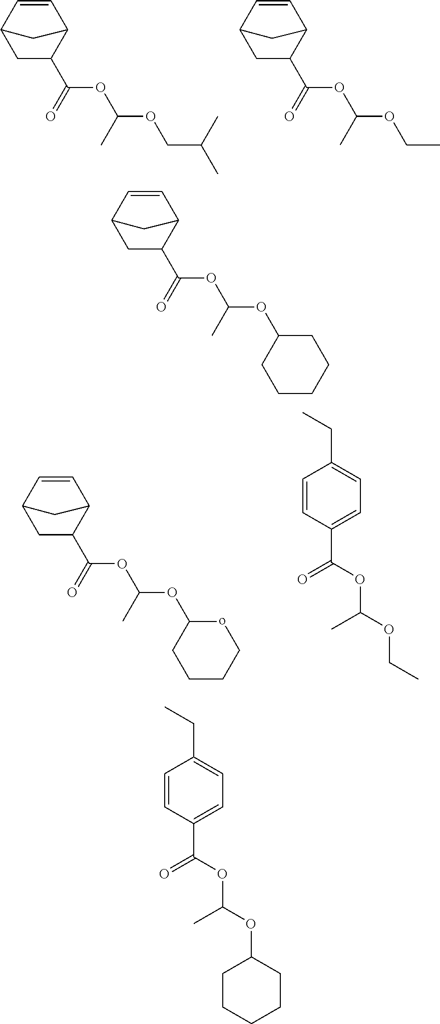

In still another example, the repeating unit having an acid-labile group of the first polymer may be derived from one or more monomers having a cyclic acetal or cyclic ketal group, for example, of the formulas:

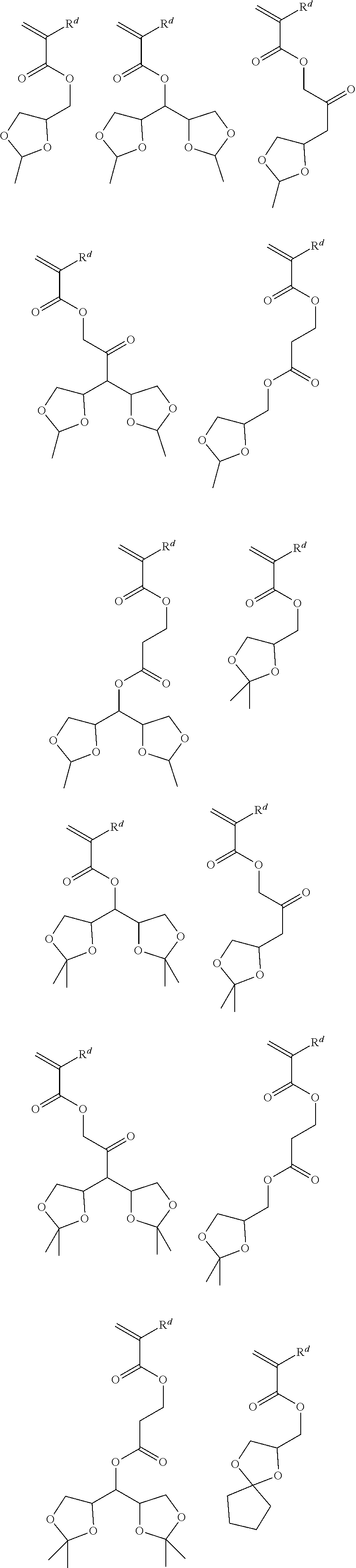

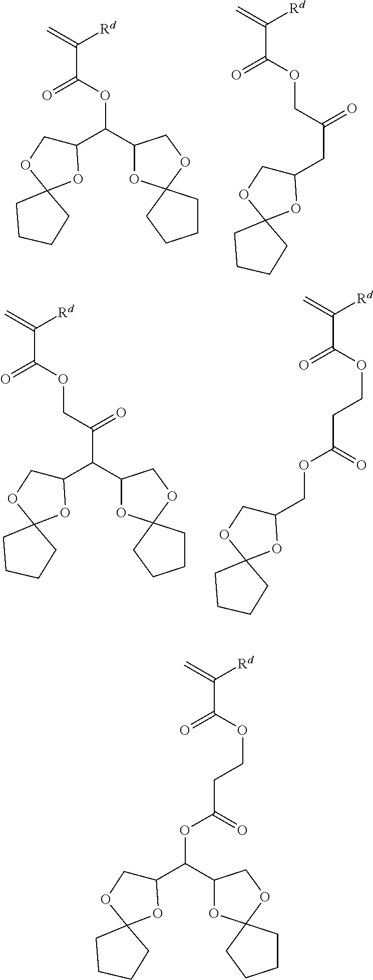

wherein R^{d} is as defined above for R^{a}.

In still another example, the repeating unit having the acid-labile group of the first polymer may be derived from one or more monomers having a tertiary alkoxy group, for example, of the formulas:

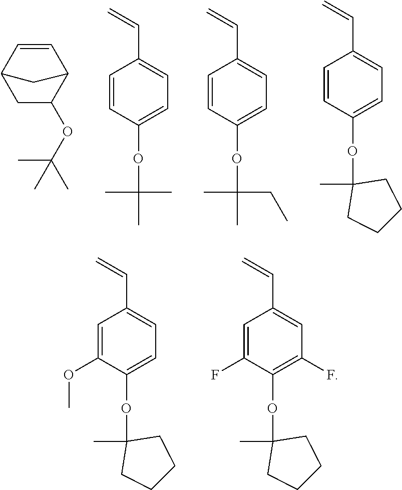

The repeating unit having an acid-labile group is typically present in the first polymer in an amount from 10 to 80 mol %, more typically from 20 to 75 mol %, still more typically from 30 to 60 mol %, based on total repeating units in the first polymer.

The first polymer may optionally include one or more additional repeating units. The additional repeating units may include, for example, one or more additional units for purposes of adjusting properties of the photoresist composition, such as etch rate and solubility. Exemplary additional units may include one or more of (meth)acrylate, vinyl aromatic, vinyl ether, vinyl ketone, and vinyl ester. The one or more additional repeating units if present in the first polymer, may be used in an amount of up to 90 mol %, typically from 3 to 50 mol %, based on total repeating units of the first polymer.

The first polymer may further include a lactone-containing repeating unit derived from a monomer of formula (2):

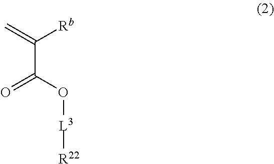

wherein R^{b} is hydrogen, fluorine, cyano, a substituted or unsubstituted C₁₋₁₀ alkyl, or a substituted or unsubstituted C₁₋₁₀ fluoroalkyl. Preferably, R^{b} is hydrogen, fluorine, or substituted or unsubstituted C₁₋₅ alkyl, typically methyl. L³ may be a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₇₋₃₀ arylalkylene, substituted or unsubstituted C₁₋₃₀ heteroarylene, or substituted or unsubstituted C₂₋₃₀ heteroarylalkylene, wherein L³ optionally may further include one or more groups chosen, for example, from —O—, —C(O)—, —C(O)—O—, —S—, —S(O)₂—, and N(R²³)—S(O)₂—, wherein R²³ may be hydrogen, a straight chain or branched C₁₋₂₀ alkyl, monocyclic or polycyclic C₃₋₂₀ cycloalkyl, or monocyclic or polycyclic C₂₋₂₀ heterocycloalkyl. R²² is a monocyclic, polycyclic, or fused polycyclic C₄₋₂₀ lactone-containing group or a monocyclic, polycyclic, or fused polycyclic C₄₋₂₀ sultone-containing group.

Non-limiting examples of monomers of formula (2) include:

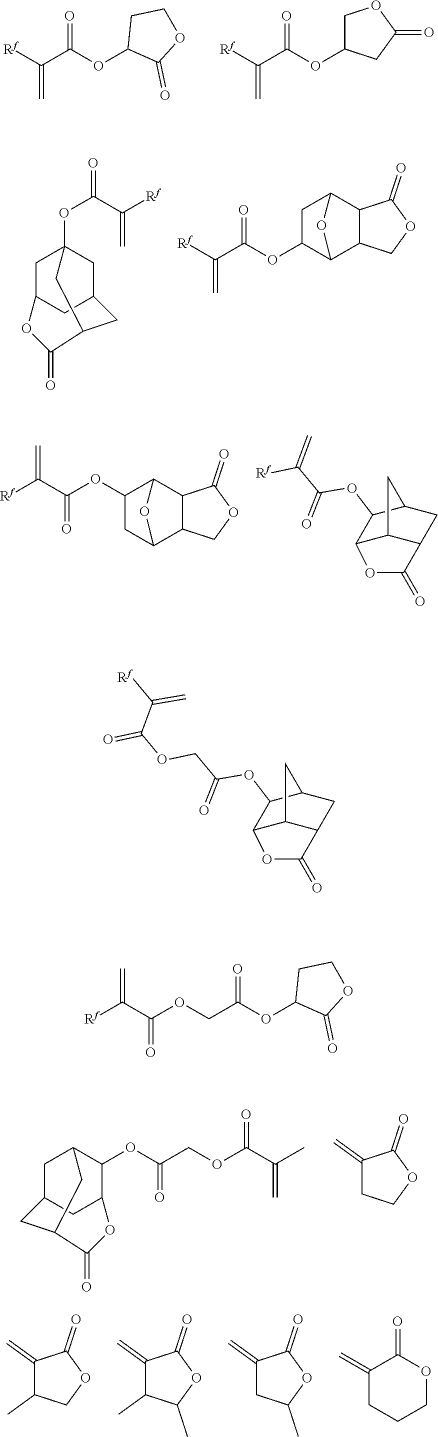

wherein R^{f} is as disclosed herein for R^{b}.

When present, the first polymer typically comprises a lactone repeating unit in an amount from 5 to 60 mol %, typically 10 to 55 mol %, more typically 20 to 50 mol % based on total moles of repeating units in the first polymer.

The first polymer may include a base-soluble repeating unit having a pKa of less than or equal to 12. For example, the base-soluble repeating unit can be derived from a monomer of formula (3):

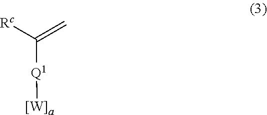

wherein R^{c} is hydrogen, fluorine, cyano, a substituted or unsubstituted C₁₋₁₀ alkyl, or a substituted or unsubstituted C₁₋₁₀ fluoroalkyl. Preferably, R^{c} is hydrogen, fluorine, or substituted or unsubstituted C₁₋₅ alkyl, typically methyl. Q¹ may be one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, or —C(O)—O—. W is a base-soluble group comprising —C(O)—OH; —C(CF₃)₂OH; an amide; an imide; or —NH—S(O)₂—Y¹ where Y¹ is F or C₁₋₄ perfluoroalkyl. In formula (3), a is an integer of 1 to 3.

Non-limiting examples of monomers of formula (3) include:

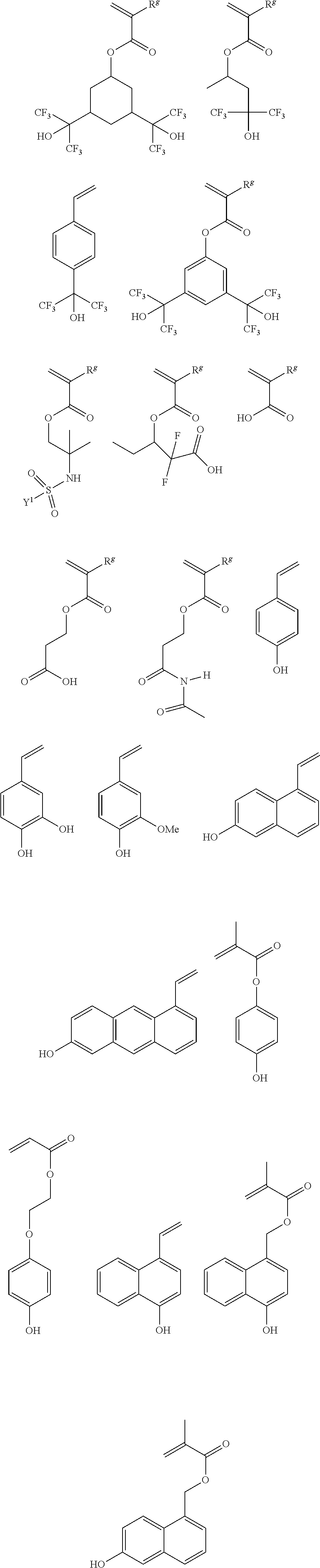

wherein R^{g} is as defined for R^{c} and Y¹ is described above.

When present, the first polymer typically comprises a base-soluble repeating unit in an amount from 5 to 60 mol %, typically from 5 to 55 mol %, more typically from 10 to 50 mol %, based on total repeating units in the first polymer.

The first polymer typically has a weight average molecular weight (M_{W}) from 1,000 to 50,000 Daltons (Da), preferably from 2,000 to 30,000 Da, more preferably from 3,000 to 20,000 Da, and still more preferably from 3,000 to 10,000 Da. The polydispersity index (PDI) of the first polymer, which is the ratio of M_{W} to number average molecular weight (Mₙ) is typically from 1.1 to 3, and more typically from 1.1 to 2. Molecular weight values are determined by gel permeation chromatography (GPC) using polystyrene standards.

The photoresist composition includes a second polymer. The second polymer comprises a repeating unit derived from one or more monomers of formula (4):

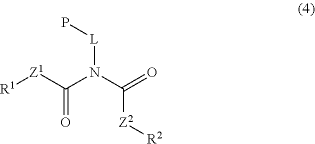

wherein, Z¹ and Z² are each independently a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —N(R³)—, —S—, or —S(O)₂—, wherein R³ is hydrogen, substituted or unsubstituted C₁₋₂₀ alkyl, substituted or unsubstituted C₁₋₂₀ heteroalkyl, substituted or unsubstituted C₃₋₂₀ cycloalkyl, or substituted or unsubstituted C₂₋₂₀ heterocycloalkyl. Optionally, Z¹ and Z² together form a ring via a single bond or a double bond between Z¹ and Z².

In formula (4), R¹ and R² may be each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, substituted or unsubstituted C₂₋₃₀ alkylheteroaryl, —OR⁴, or —N(R⁵)₂, wherein R⁴ and R⁵ are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl. Optionally, R¹ and R² together form a ring via a single bond or a divalent linking group comprising one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —C(O)—O—, —C(O)—N(R^{2a})—, —S—, —S(O)₂—, or N(R^{2a})—S(O)₂— wherein R^{2a} is hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

In formula (4), L is a single bond or a multivalent linking group such as a divalent linking group, a trivalent linking group, or a tetravalent linking group. For example, L can be a single bond or a divalent linking group chosen from one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —C(O)—O—, —C(O)—N(R^{2b})—, —S—, —S(O)₂—, or N(R^{2b})—S(O)₂— wherein R^{2b} is hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

In formula (4), P is a polymerizable group. Typically, the polymerizable group is chosen from (meth)acrylic, vinyl, and norbornyl.

In formula (4), L is optionally a multivalent linking group further comprising an additional group of the formula:

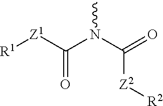

wherein Z¹, Z², R¹, and R² are as described above.

In some embodiments, the second polymer may include a repeating unit derived from one or more monomers of formula (4a):

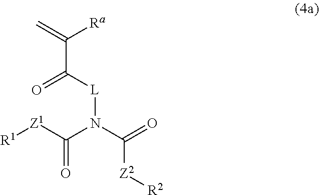

In formula (4a), R^{a} is hydrogen, fluorine, cyano, a substituted or unsubstituted C₁₋₁₀ alkyl, or a substituted or unsubstituted C₁₋₁₀ fluoroalkyl. L is as defined for formula (4). For example, L is a single bond or a divalent linking group including one or more groups chosen from substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —C(O)O—, —OC(O)—, —N(R²⁵)—, —S—, or —S(O)₂—, wherein R²⁵ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl.

In formula (4a), Z¹ and Z² are the same, wherein Z¹ and Z² are chosen from a single bond, —O—, a divalent linking group comprising a group of the formula —C(O)—, or a divalent linking group comprising a group of the formula —C(O)—O—. R¹ and R² are each independently substituted or unsubstituted C₁₋₃₀ alkyl; and optionally, R¹ and R² together form a ring via a single bond or a divalent linking group.

Non-limiting examples of the monomers of formula (4) and/or (4a) include:

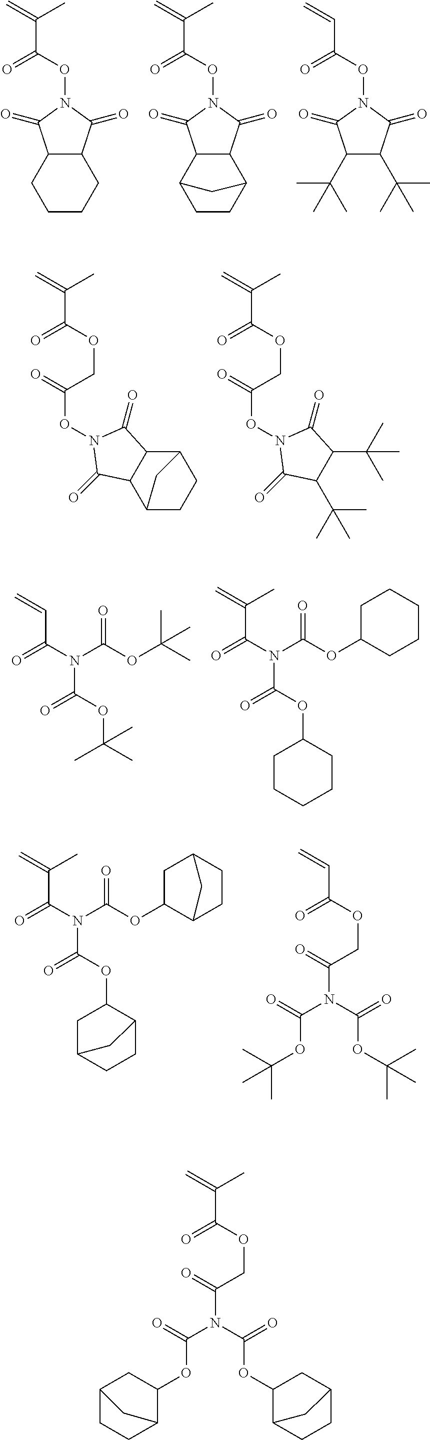

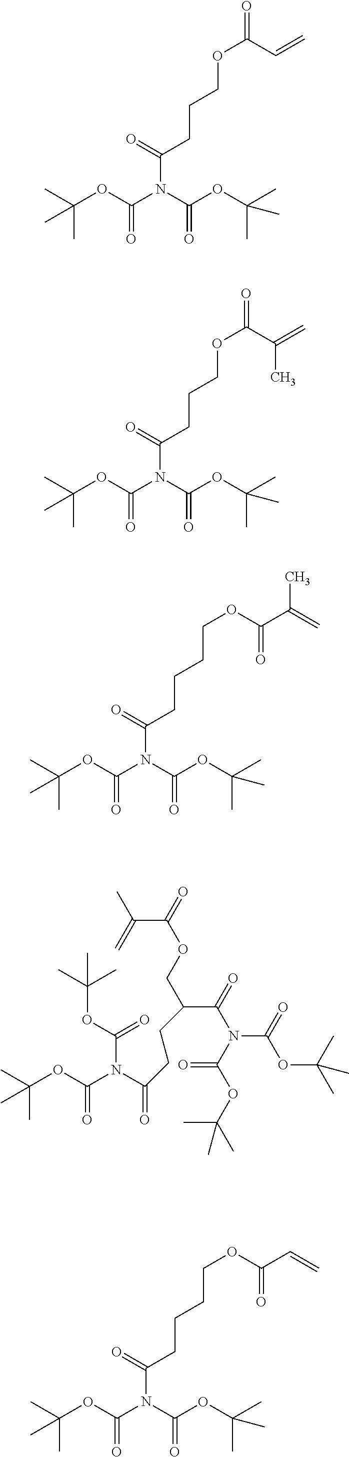

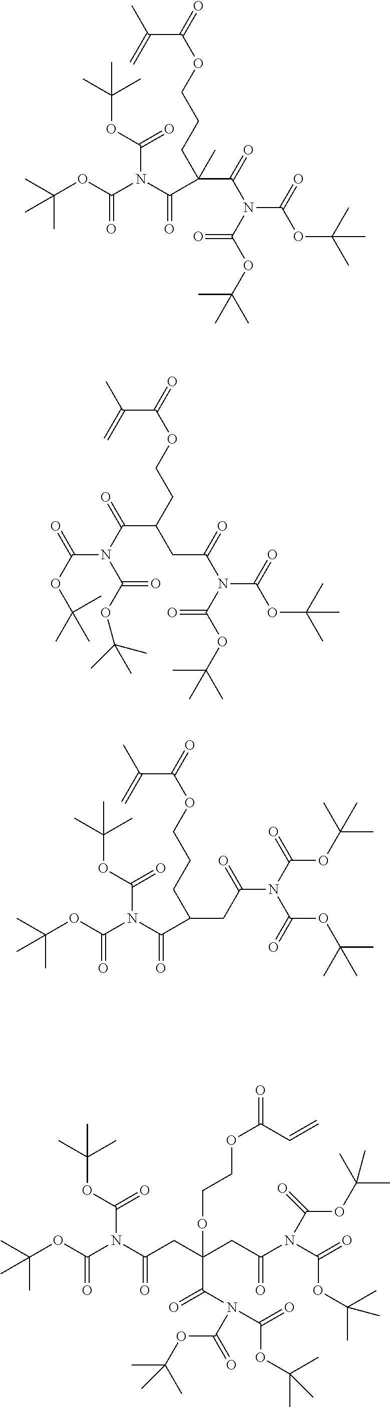

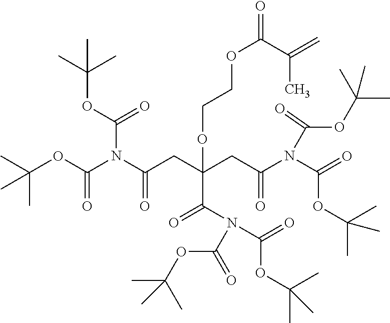 [SMILES: C=C(C)C(=O)OCCOC(CC(=O)N(C(=O)OC(C)(C)C)C(=O)OC(C)(C)C)(CC(=O)N(C(=O)OC(C)(C)C)C(=O)OC(C)(C)C)C(=O)N(C(=O)OC(C)(C)C)C(=O)OC(C)(C)C]

The monomers above that include a single di(Boc) amide moiety may be referred to as a single-armed monomer. Other exemplary monomers include more than one di(Boc)amide moiety and may be referred to as double-armed monomers. For a polymer comprising a structural unit derived from the single-armed monomer, one carboxyl functional group may be generated on the structural unit derived from the single-armed monomer upon hydrolysis. For a polymer comprising a structural unit derived from the double-armed monomer, two carboxyl functional groups may be generated for each structural unit derived from the double-armed monomer upon hydrolysis. Similarly, for a polymer comprising a structural unit derived from the triple-armed monomer, three carboxyl functional groups may be generated for each structural unit derived from the triple-armed monomer upon hydrolysis. This can be beneficial for making the polymer more hydrophilic upon contacting an aqueous alkaline developer. Examples of double-armed monomers include those described below (e.g., Monomer 17 from the Examples).

The second polymer may optionally further include one or more additional repeating units different from the repeating unit derived from the one or more monomers of formula (4). For example, the second polymer may optionally include one or more additional repeating units as described above for the optional additional repeating units of the first polymer, such as a repeating unit having an acid-labile group. The one or more additional units if present in the second polymer may be used in an amount of up to 70 mol %, and typically from 3 to 50 mol %, based on total repeating units in the second polymer.

In some aspects, the second polymer may include one or more repeating units derived from “base-labile” monomers of formula E1, E2, or E3, as described below.

The second polymer typically has a M_{w} from 1,000 to 50,000 Da, preferably from 2,000 to 30,000 Da, more preferably 3,000 to 20,000 Da, and still more preferably from 3,000 to 10,000 Da. The PDI of the polymer is typically from 1.1 to 3, and more typically from 1.1 to 2. Molecular weights are determined by GPC using polystyrene standards.

The first and second polymers may be prepared using any suitable methods in the art. For example, one or more monomers corresponding to the repeating units described herein may be combined, or fed separately, using suitable solvent(s) and initiator, and polymerized in a reactor. For example, the first and second polymers may be obtained by polymerization of the respective monomers under any suitable conditions, such as by heating at an effective temperature, irradiation with actinic radiation at an effective wavelength, or a combination thereof.

The photoresist composition further comprises a photoacid generator (PAG). Suitable PAGs can generate an acid that, during post-exposure bake (PEB), causes cleavage of acid-labile groups present on a polymer of the photoresist composition. The PAG may be included as a non-polymerized PAG compound (as disclosed below), as a repeating unit of a polymer having a PAG moiety that is derived from a polymerizable PAG compound, or a combination thereof. For example, the first polymer optionally may comprise a repeating unit comprising a PAG, for example a repeating unit derived from one or more monomers of formula (5):

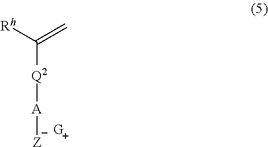

In formula (5), R^{h} is hydrogen, fluorine, cyano, a substituted or unsubstituted C₁₋₁₀ alkyl, or a substituted or unsubstituted C₁₋₁₀ fluoroalkyl. Preferably, R^{h} is hydrogen, fluorine, or substituted or unsubstituted C₁₋₅ alkyl, typically methyl. Q² is a single bond or a divalent linking group chosen from one or more of a heteroatom, substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, or a combination thereof. Preferably, Q² may include 1 to 10 carbon atoms and at least one heteroatom, more preferably —C(O)—O—.

In formula (5), A is one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, or substituted or unsubstituted C₁₋₃₀ heteroarylene. Preferably, A is a divalent C₁₋₃₀ perfluoroalkylene group that is optionally substituted. Z is an anionic moiety comprising sulfonate, carboxylate, an anion of a sulfonamide, an anion of a sulfonimide, or a methide anion. G⁺ is an organic cation as described below.

Exemplary monomers of formula (5) include the following:

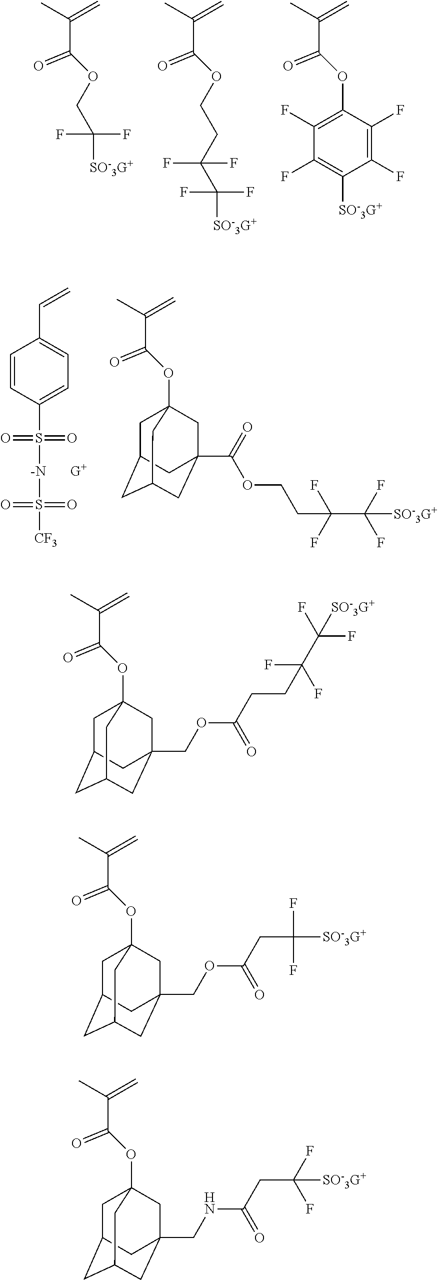

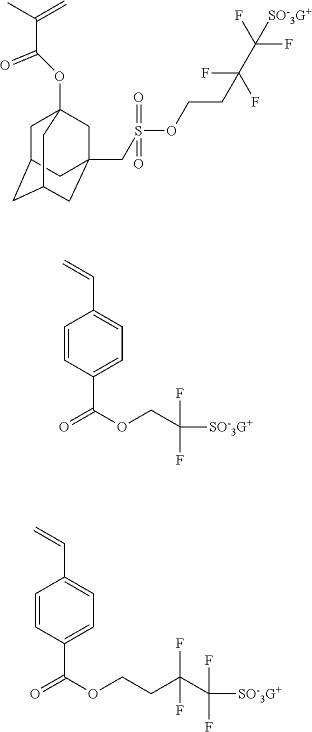

wherein G⁺ is an organic cation. Organic cations include, for example, iodonium cations substituted with two alkyl groups, aryl groups, or a combination of alkyl and aryl groups; and sulfonium cations substituted with three alkyl groups, aryl groups, or a combination of alkyl and aryl groups. In some embodiments, G⁺ is an iodonium cation substituted with two alkyl groups, aryl groups, or a combination of alkyl and aryl groups; or a sulfonium cation substituted with three alkyl groups, aryl groups, or a combination of alkyl and aryl groups. In some embodiments, G⁺ may be one or more of a substituted sulfonium cation having the formula (5A) or an iodonium cation having the formula (5B):

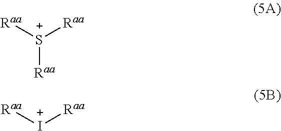

wherein, each R^{aa} is independently a C₁₋₂₀ alkyl group, a C₁₋₂₀ fluoroalkyl group, a C₃₋₂₀ cycloalkyl group, a C₃₋₂₀ fluorocycloalkyl group, a C₂₋₂₀ alkenyl group, a C₂₋₂₀ fluoroalkenyl group, a C₆₋₃₀ aryl group, a C₆₋₃₀ fluoroaryl group, C₆₋₃₀ iodoaryl group, a C₁₋₃₀ heteroaryl group, a C₇₋₂₀ arylalkyl group, a C₇₋₂₀ fluoroarylalkyl group, a C₂₋₃₀ heteroarylalkyl group, or a C₂₋₃₀ fluoroheteroarylalkyl group, each of which is substituted or unsubstituted, wherein each R^{aa} is either separate or connected to another group R^{aa} via a single bond or a divalent linking group to form a ring. Each R^{aa} optionally may include as part of its structure one or more groups selected from —O—, —C(O)—, —C(O)—O—, —C₁₋₁₂ hydrocarbylene-, —O—(C₁₋₁₂ hydrocarbylene)-, —C(O)—O—(C₁₋₁₂ hydrocarbylene)-, and —C(O)—O—(C₁₋₁₂ hydrocarbylene)-O—. Each R^{aa} independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups. Suitable divalent linking groups for connection of R^{aa} groups include, for example, —O—, —S—, —Te—, —Se—, —C(O)—, —C(S)—, —C(Te), S(O)—, S(O)₂—, —N(R)— or —C(Se)—, substituted or unsubstituted C₁₋₅ alkylene, and combinations thereof, wherein R is hydrogen, C₁₋₂₀ alkyl, C₁₋₂₀ heteroalkyl, C₆₋₃₀ aryl, or C₁₋₃₀ heteroaryl, each of which except for hydrogen can be substituted or unsubstituted.

Exemplary sulfonium cations of formula (5A) include the following:

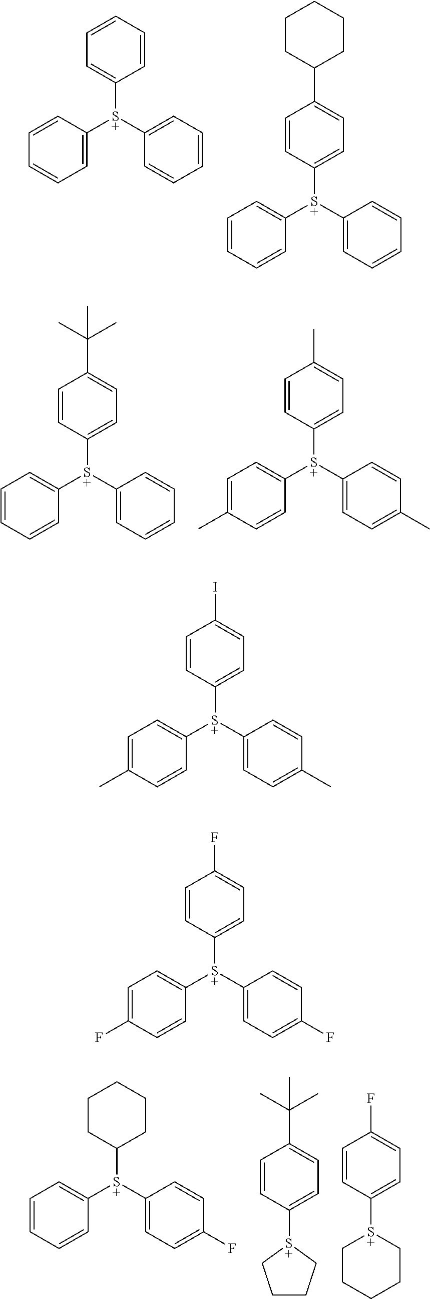

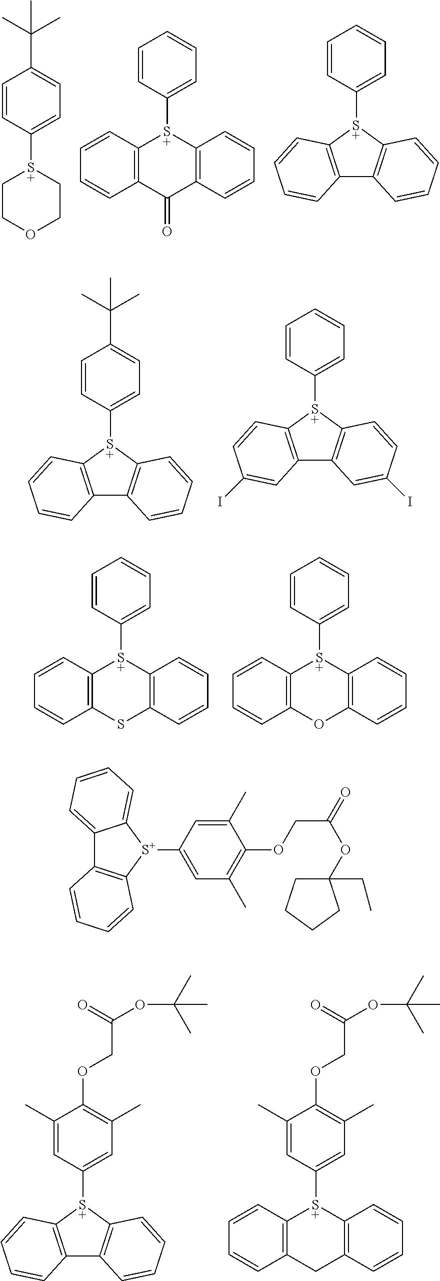

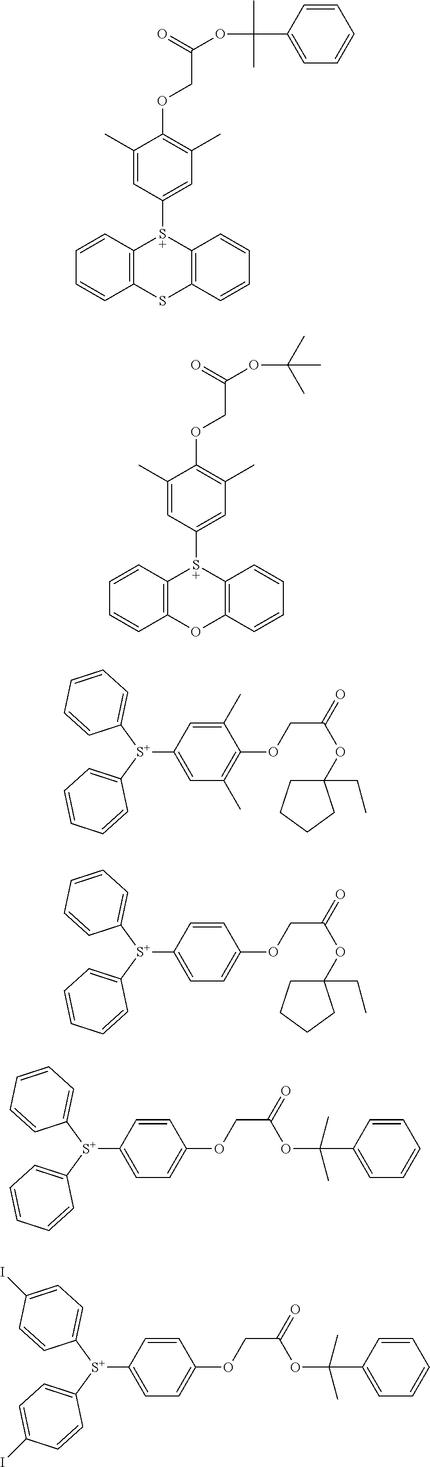 [SMILES: Cc1cc([S+]2c3ccccc3Sc3ccccc32)cc(C)c1OCC(=O)OC(C)(C)c1ccccc1 ; Cc1cc([S+]2c3ccccc3Oc3ccccc32)cc(C)c1OCC(=O)OC(C)(C)C ; CCC1(OC(=O)COc2c(C)cc([S+](c3ccccc3)c3ccccc3)cc2C)CCCC1 ; CCC1(OC(=O)COc2ccc([S+](c3ccccc3)c3ccccc3)cc2)CCCC1 ; CC(C)(OC(=O)COc1ccc([S+](c2ccccc2)c2ccccc2)cc1)c1ccccc1 ; CC(C)(OC(=O)COc1ccc([S+](c2ccc(I)cc2)c2ccc(I)cc2)cc1)c1ccccc1]

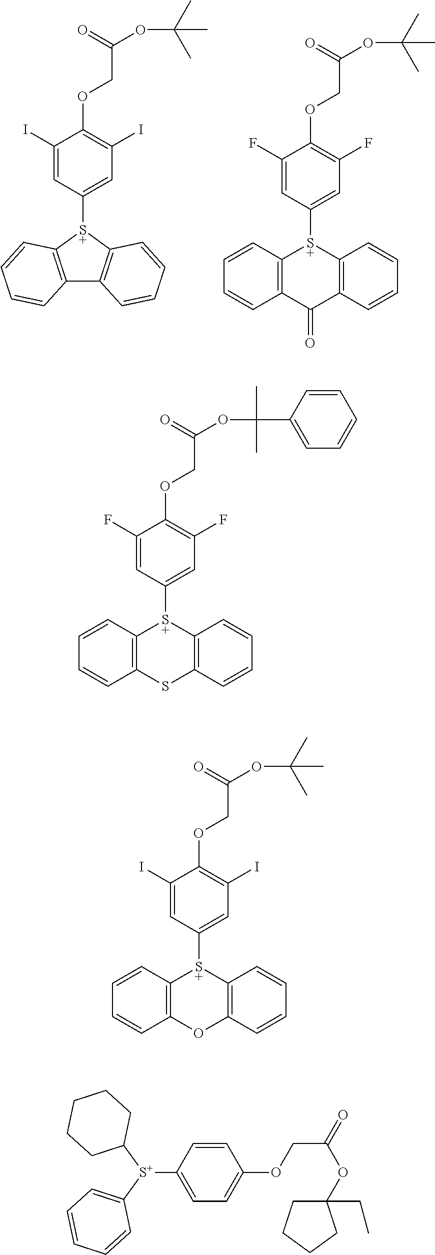 [SMILES: CC(C)(C)OC(=O)COc1c(I)cc(-[s+]2c3ccccc3c3ccccc32)cc1I ; CC(C)(C)OC(=O)COc1c(F)cc(-[s+]2c3ccccc3c(=O)c3ccccc32)cc1F ; CC(C)(OC(=O)COc1c(F)cc([S+]2c3ccccc3Sc3ccccc32)cc1F)c1ccccc1 ; CC(C)(C)OC(=O)COc1c(I)cc([S+]2c3ccccc3Oc3ccccc32)cc1I ; CCC1(OC(=O)COc2ccc([S+](c3ccccc3)C3CCCCC3)cc2)CCCC1]

Exemplary iodonium cations of formula (5B) include the following:

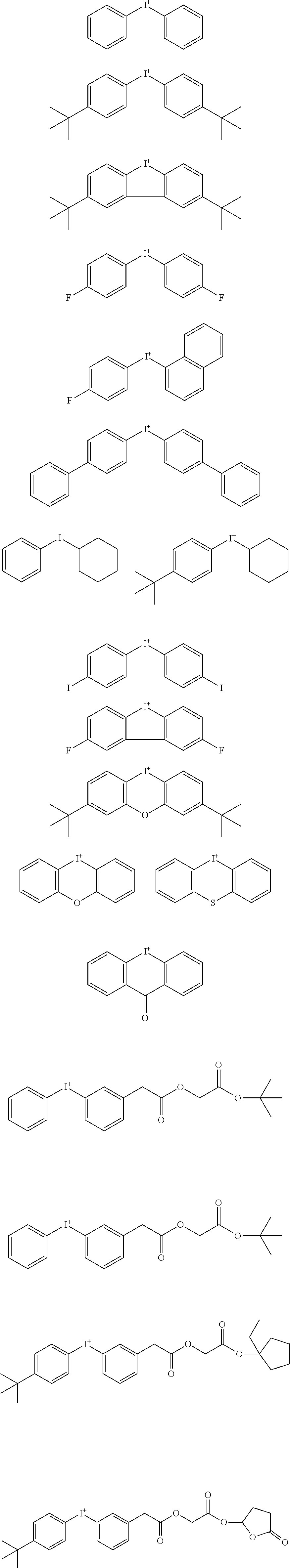

PAGs that are onium salts typically comprise an organic anion having a sulfonate group or a non-sulfonate type group, such as a sulfonamidate group, a sulfonimidate group, a methide group, or a borate group.

Exemplary organic anions having a sulfonate group include the following:

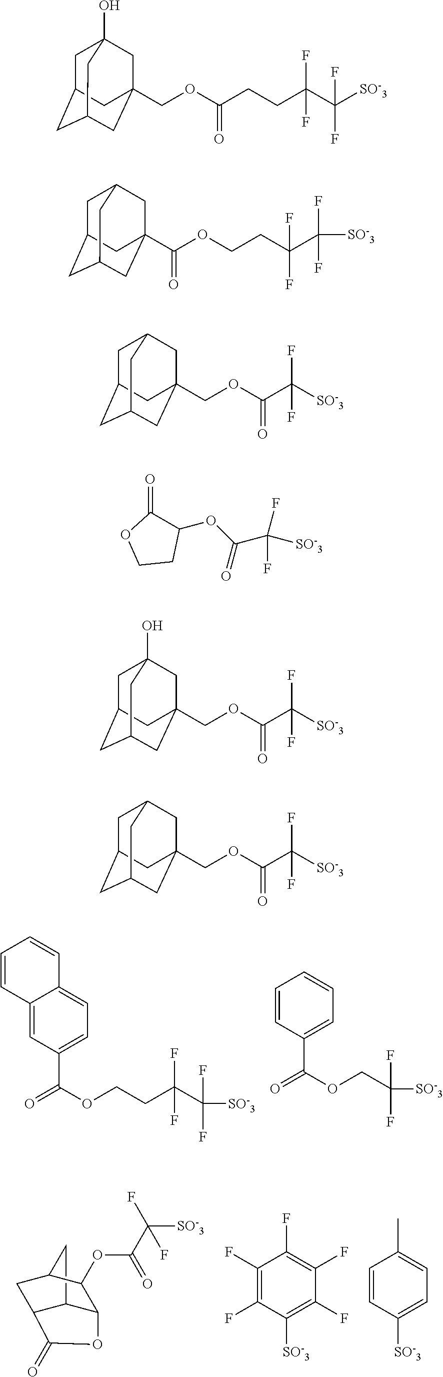

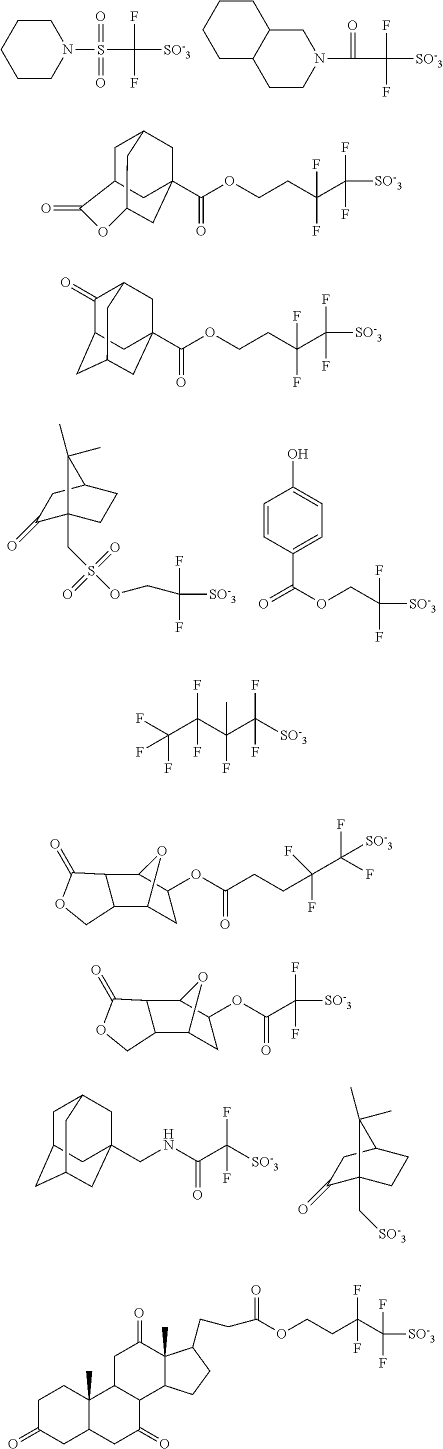

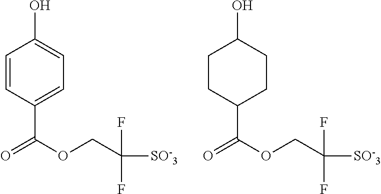

Exemplary non-sulfonated anions include the following.

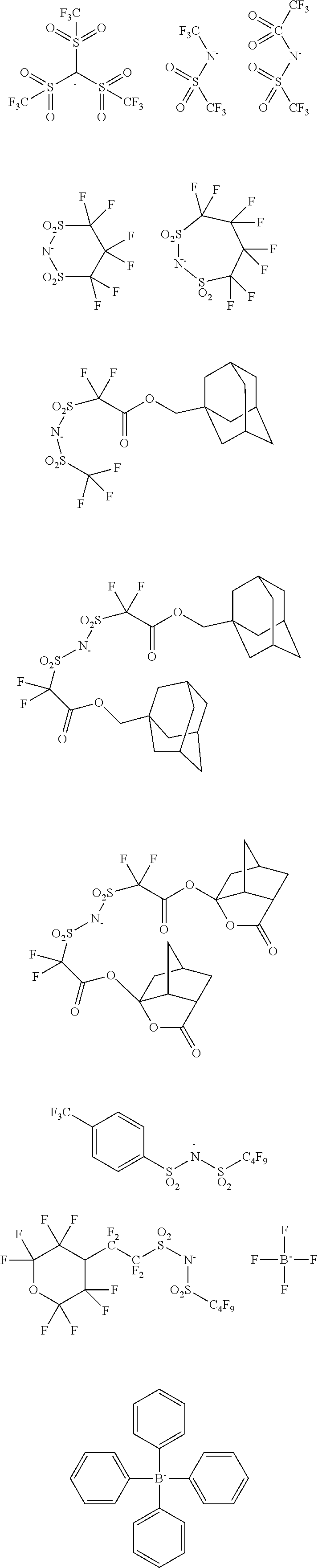

The photoresist composition may optionally comprise a plurality of PAGs. The plural PAGs may be polymeric, non-polymeric, or may include both polymeric and non-polymeric PAGs. Preferably, each of the plurality of PAGs is non-polymeric.

In one or more aspects, the photoresist composition may include a first photoacid generator that includes a sulfonate group on the anion, and the photoresist composition may include a second photoacid generator that is non-polymeric, wherein the second photoacid generator may include an anion that is free of sulfonate groups.

Typically, when the photoresist composition includes one or more non-polymerized photoacid generators, they are present in the photoresist composition in a combined amount from 1 to 65 wt %, more typically from 5 to 55 wt %, and still more typically from 8 to 30 wt %, based on total solids of the photoresist composition.

The first polymer may include one or more repeating unit(s) comprising a photoacid generator. If used in the first polymer, such unit(s) is typically present in an amount from 1 to 15 mol %, more typically from 1 to 10 mol %, and still more typically from 2 to 6 mol %, based on total repeating units in the first polymer.

The second polymer may optionally comprise a repeating unit comprising a PAG that is derived from one or more monomers of formula (5), as disclosed above. The second polymer may include a repeating unit or units comprising a PAG in a typical amount from 1 to 10 mol %, more typically from 1 to 8 mol %, and still more typically from 2 to 6 mol %, based on total repeating units in the second polymer.

The photoresist compositions further include a solvent for dissolving the components of the composition and facilitating its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol, 4-methyl-2-pentanol, and diacetone alcohol (4-hydroxy-4-methyl-2-pentanone); propylene glycol monomethyl ether (PGME); ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents are PGME, PGMEA, EL, GBL, HBM, CHO, and combinations thereof. The total solvent content (i.e., cumulative solvent content for all solvents) in the photoresist compositions is typically from 40 to 99 wt %, for example, from 70 to 99 wt %, or from 85 to 99 wt %, based on total solids of the photoresist composition. The desired solvent content will depend, for example, on the desired thickness of the coated photoresist layer and coating conditions.

The photoresist composition typically includes the first polymer and the second polymer in a weight ratio of 1:1 to 1,000:1, for example, from 1:1 to 100:1, or from 1:1 to 20:1, or from 1:1 to 10:1.

In the photoresist compositions of the invention, the first polymer and the second polymer are typically present together in the photoresist composition in an amount from 10 to 99.9 wt %, typically from 25 to 99 wt %, and more typically from 50 to 95 wt %, based on total solids of the photoresist composition. It will be understood that total solids includes the first and second polymers, PAGs, and other non-solvent components.

The photoresist composition typically includes from 0.1 to 20 wt % of the second polymer, based on the total solids of the photoresist composition. For example, the photoresist composition preferably includes from 0.1 to 10 wt % of the second polymer or includes from 0.1 to 5 wt % of the second polymer, each based on the total solids of the photoresist composition.

In some aspects, the photoresist composition may further include a material that comprises one or more base-labile groups (a “base-labile material”). As referred to herein, base-labile groups are functional groups that can undergo cleavage reaction to provide polar groups such as hydroxyl, carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the photoresist composition that comprises the base-labile group. Thus, for instance, a base-labile group will be substantially inert during pre-exposure soft-bake, exposure, and post-exposure bake steps. By “substantially inert” it is meant that ≤5%, typically ≤1%, of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26 N aqueous solution of TMAH may be used for single puddle development or dynamic development, e.g., where the 0.26 N TMAH developer is dispensed onto an imaged photoresist layer for a suitable time such as 10 to 120 seconds (s). An exemplary base-labile group is an ester group, typically a fluorinated ester group. Preferably, the base-labile material is substantially not miscible with and has a lower surface energy than the first and second polymers, and other solid components of the photoresist composition. When coated on a substrate, the base-labile material can thereby segregate from other solid components of the photoresist composition to a top surface of the formed photoresist layer.

In some aspects, the base-labile material is a polymeric material, also referred to herein as a base-labile polymer, which may include one or more repeating units comprising one or more base-labile groups. For example, the base-labile polymer may comprise a repeating unit comprising 2 or more base-labile groups that are the same or different. A preferred base-labile polymer comprises at least one repeating unit comprising 2 or more base-labile groups, for example a repeating unit comprising 2 or 3 base-labile groups.

The base-labile polymer may be a polymer comprising a repeating unit derived from one or more monomers of formula (E1)

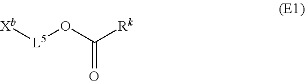

wherein X^{b} is a polymerizable group selected from vinyl and acrylic, L⁵ is a divalent linking group comprising one or more of substituted or unsubstituted linear or branched C₁₋₂₀ alkylene, substituted or unsubstituted C₃₋₂₀ cycloalkylene, —C(O)—, or —C(O)O—; and R^{k} is a substituted or unsubstituted C₁₋₂₀ fluoroalkyl group provided that the carbon atom bonded to the carbonyl (C═O) in formula (E1) is substituted with at least one fluorine atom.

Exemplary monomers of formula (E1) include the following:

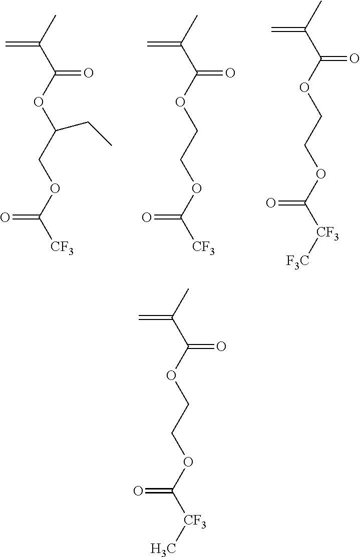

The base-labile polymer may include a repeating unit including two or more base-labile groups. For example, the base-labile polymer can include a repeating unit derived from one or more monomers of formula (E2)

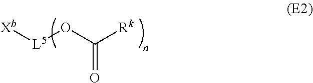

wherein X^{b} and R^{k} are as defined in formula E1; L⁶ is a polyvalent linking group comprising one or more of substituted or unsubstituted straight chain or branched C₁₋₂₀ alkylene, substituted or unsubstituted C₃₋₂₀ cycloalkylene, —C(O)—, or —C(O)O—; and n is an integer of 2 or more, for example 2 or 3.

Exemplary monomers of formula (E2) include the following:

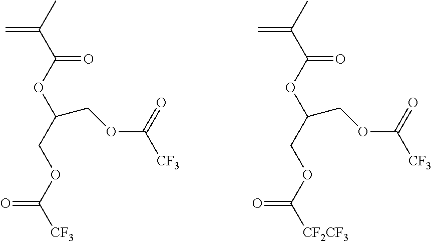

The base-labile polymer may include a repeating unit including one or more base-labile groups. For example, the base-labile polymer can include a repeating unit derived from one or more monomers of formula (E3):

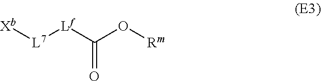

wherein X^{b} is as defined in formula (E1); L⁷ is a divalent linking group comprising one or more of substituted or unsubstituted straight chain or branched C₁₋₂₀ alkylene, substituted or unsubstituted C₃₋₂₀ cycloalkylene, —C(O)—, or —C(O)O—; L^{f} is a substituted or unsubstituted C₁₋₂₀ fluoroalkylene group wherein the carbon atom bonded to the carbonyl (C═O) in formula (E1) is substituted with at least one fluorine atom; and R^{m} is substituted or unsubstituted straight chain or branched C₁₋₂₀ alkyl, or substituted or unsubstituted C₃₋₂₀ cycloalkyl.

Exemplary monomers of formula (E3) include the following:

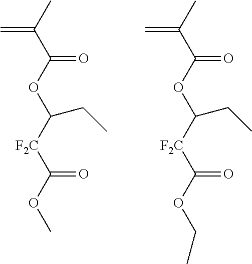 [SMILES: C=C(C)C(=O)OC(CC)C(F)(F)C(=O)OC ; C=C(C)C(=O)OC(CC)C(F)(F)C(=O)OCC]

In a further preferred aspect of the invention, a base-labile polymer may comprise one or more base-labile groups and one or more acid-labile groups, such as one or more acid-labile ester moieties (e.g. t-butyl ester) or acid-labile acetal groups. For example, the base-labile polymer may comprise a repeating unit including a base-labile group and an acid-labile group, i.e., wherein both a base-labile group and an acid-labile group are present on the same repeating unit. In another example, the base-labile polymer may comprise a first repeating unit comprising a base-labile group and a second repeating unit comprising an acid-labile group. Preferred photoresists of the invention can exhibit reduced defects associated with a resist relief image formed from the photoresist composition.

The base-labile polymer may be prepared using any suitable methods in the art, including those described herein for the first and second polymers. For example, the base-labile polymer may be obtained by polymerization of the respective monomers under any suitable conditions, such as by heating at an effective temperature, irradiation with actinic radiation at an effective wavelength, or a combination thereof. Additionally, or alternatively, one or more base-labile groups may be grafted onto the backbone of a polymer using suitable methods.

In some aspects, the base-labile material is a single molecule comprising one more base-labile ester groups, preferably one or more fluorinated ester groups. The base-labile materials that are single molecules typically have a M_{w} in the range from 50 to 1,500 Da. Exemplary base-labile materials include the following:

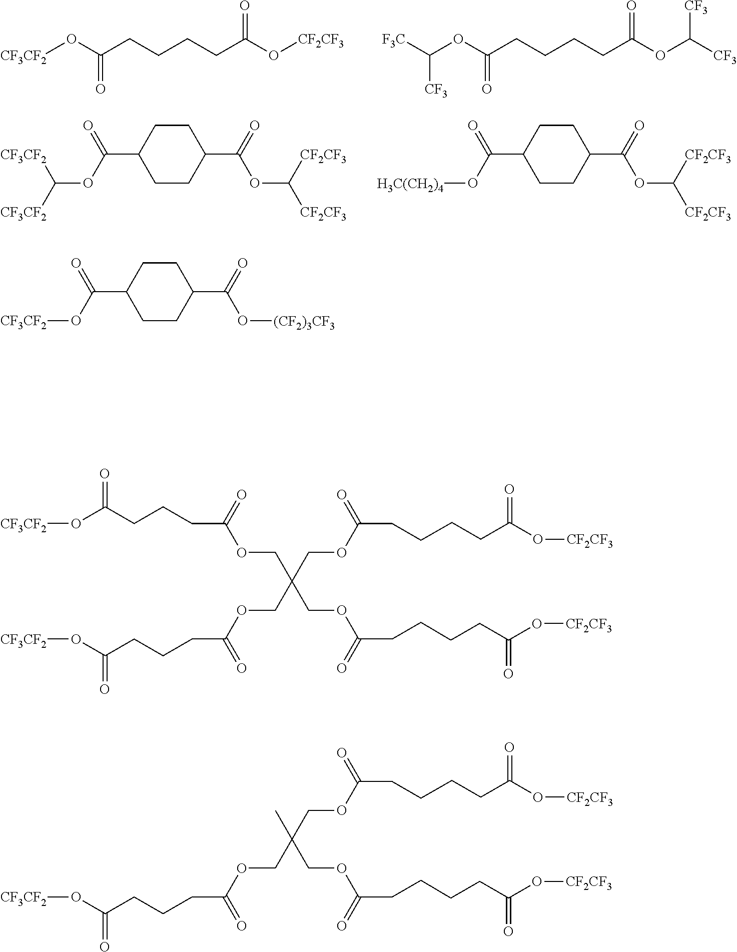

Additionally, or alternatively, to the base-labile polymer, the photoresist compositions may further include one or more polymers in addition to and different from the first and second polymers described above. For example, the photoresist compositions may include an additional polymer as described above but different in composition, or a polymer that is similar to those described above but does not include each of the requisite repeating units. Additionally, or alternatively, the one or more additional polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The photoresist composition may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the photoresist compositions in an amount of from 0.01 to 10 wt %, based on total solids of the photoresist composition.

Photo-decomposable quenchers generate a weak acid upon irradiation. The acid generated from a photo-decomposable quencher is not strong enough to react rapidly with acid-labile groups that are present in the resist matrix. Exemplary photo-decomposable quenchers include, for example, photo-decomposable cations, and preferably those also useful for preparing strong acid generator compounds, paired with an anion of a weak acid (pKa>−1) such as, for example, an anion of a C₁₋₂₀ carboxylic acid or C₁₋₂₀ sulfonic acid. Exemplary carboxylic acids include formic acid, acetic acid, propionic acid, tartaric acid, succinic acid, cyclohexanecarboxylic acid, benzoic acid, salicylic acid, and the like. Exemplary sulfonic acids include p-toluene sulfonic acid, camphor sulfonic acid and the like. In a preferred embodiment, the photo-decomposable quencher is a photo-decomposable organic zwitterion compound such as diphenyliodonium-2-carboxylate.

The photo-decomposable quencher may be in non-polymeric or polymer-bound form. When in polymeric form, the photo-decomposable quencher is present in polymerized units on the first polymer or second polymer. The polymerized units containing the photo-decomposable quencher are typically present in an amount from 0.1 to 30 mole %, preferably from 1 to 10 mole % and more preferably from 1 to 2 mole %, based on total repeating units of the polymer.

Exemplary basic quenchers include, for example: linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher is present in polymerized units on the first polymer or second polymer. The polymerized units containing the quencher are typically present in an amount of from 0.1 to 30 mole %, preferably from 1 to 10 mole % and more preferably from 1 to 2 mole %, based on total repeating units of the polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the photoresist composition further includes a surfactant polymer including a fluorine-containing repeating unit.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP 3000, AP 8000, and AP 9000S designations, available from DuPont Electronics & Imaging (Marlborough, Mass.).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, 1,000 to 2,500 rpm, for a period from 15 to 120 seconds to obtain a layer of the photoresist composition on the substrate. It will be appreciated by those skilled in the art that the thickness of the coated layer may be adjusted by changing the spin speed and/or the solids content of the composition. A photoresist layer formed from the compositions of the invention typically has a dried layer thickness from 10 to 500 nanometers (nm), preferably from 15 to 200 nm, and more preferably from 20 to 120 nm.

The photoresist composition is typically next soft-baked to minimize the solvent content in the layer, thereby forming a tack-free coating and improving adhesion of the layer to the substrate. The soft bake is performed, for example, on a hotplate or in an oven, with a hotplate being typical. The soft bake temperature and time will depend, for example, on the photoresist composition and thickness. The soft bake temperature is typically from 80 to 170° C., and more typically from 90 to 150° C. The soft bake time is typically from 10 seconds to 20 minutes, more typically from 1 minute to 10 minutes, and still more typically from 1 minute to 2 minutes. The heating time can be readily determined by one of ordinary skill in the art based on the ingredients of the composition.

The photoresist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nm, sub-300 nm or sub-200 nm, with 248 nm (KrF), 13.5 nm (EUV) wavelengths or e-beam lithography being preferred. The methods find use in immersion or dry (non-immersion) lithography techniques. The exposure energy is typically from 1 to 200 millijoules per square centimeter (mJ/cm²), preferably from 10 to 100 mJ/cm² and more preferably from 20 to 50 mJ/cm², dependent upon the exposure tool and components of the photoresist composition.

Following exposure of the photoresist layer, a post-exposure bake (PEB) of the exposed photoresist layer is performed. The PEB can be conducted, for example, on a hotplate or in an oven, with a hotplate being typical. Conditions for the PEB will depend, for example, on the photoresist composition and layer thickness. The PEB is typically conducted at a temperature from 80 to 150° C., and a time from 30 to 120 seconds. A latent image defined by the polarity-switched (exposed regions) and unswitched regions (unexposed regions) is formed in the photoresist.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 98 wt % or more, or 100 wt %, based on total weight of the developer. Suitable organic solvents for the NTD developer include, for example, those chosen from ketones, esters, ethers, hydrocarbons, and mixtures thereof. The developer is typically 2-heptanone or n-butyl acetate.

A coated substrate may be formed from the photoresist compositions of the invention. Such a coated substrate includes: (a) a substrate having one or more layers to be patterned on a surface thereof; and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following examples.

### EXAMPLES

Synthesis of Monomer 1: Methacrylamide (10.0 g, 1.0 equivalent) and dimethylaminopyridine (1.45 g, 0.1 equivalent) are dissolved in 250 mL of dichloromethane. Di-tert-butyl dicarbonate (53.9 g, 2.1 equivalents) is added slowly and the reaction is left stirring at room temperature for 16 hours. The reaction mixture is then washed with saturated sodium bicarbonate, water, and brine, and then dried over magnesium sulfate. The solvent is removed under reduced pressure to give Monomer 1.

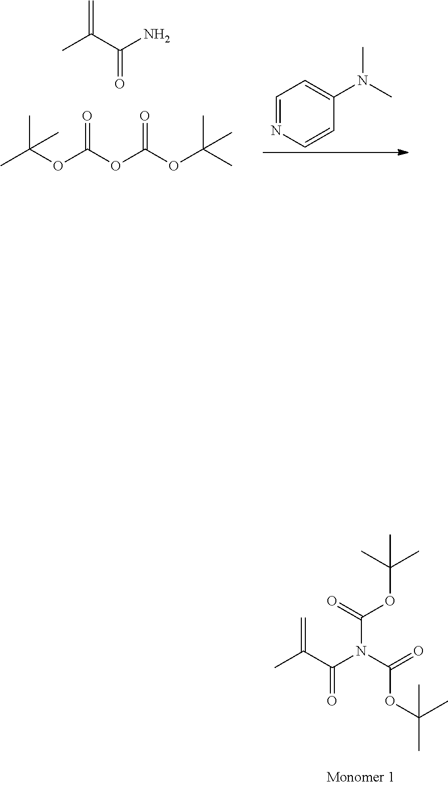

Synthesis of Monomer 2: N-hydroxy-5-norbornane-2,3-dicarboxylic acid imide (15.8 g, 1.0 equivalent) and triethylamine (13.2 g, 1.5 equivalent) are dissolved in 200 mL dichloromethane. The reaction mixture is cooled to 0° C. and methacryloyl chloride (10.0 g, 1.1 equivalent) is slowly added thereto. The reaction mixture continues stirring at 23-25° C. for 16 hours. The reaction mixture is then washed with saturated sodium bicarbonate, water, and brine, and is then dried over magnesium sulfate. The solvent is removed under reduced pressure to give Monomer 2.

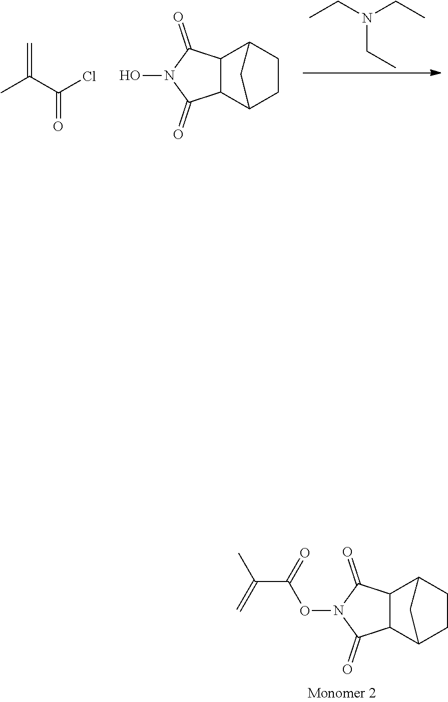

Synthesis of Monomer 13A, 13B, 13C, and 13D: Monomer 13A was prepared as shown Scheme 1:

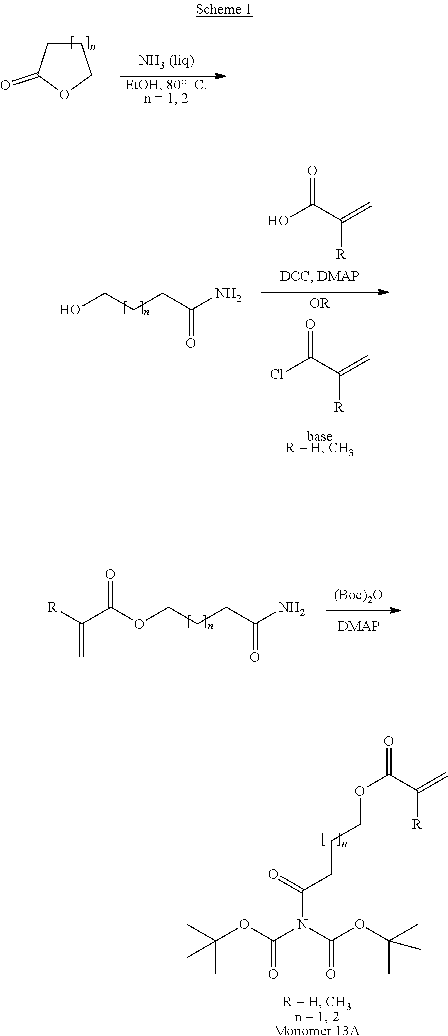

wherein R═CH₃, n=2, (Boc)₂O is di-tert-butyl dicarbonate, and DMAP is 4-dimethylaminopyridine.

Similarly, Monomer 13B (R═CH₃, n=1), Monomer 13C (R═H, n=2), and Monomer 13D (R═H, n=1) are prepared as shown in Scheme 1, where (Boc)₂O and DMAP are as defined above.

Synthesis of 5-Hydroxypentanamide: A 2-L autoclave was charged with tetrahydro-2H-pyran-2-one (80.0 g, 799.04 mmol) in ethanol (200 mL, 2.5 vol), the of the contents of the autoclave were cooled below −30° C., and liquid ammonia (400 mL, 5 vol) was added thereto. The autoclave was sealed, and the reaction mixture was heated to 90-100° C. at 500-575 psi for 24 h. Then, the reaction mixture cooled to room temperature and a resulting solid was filtered from the mixture. The wet cake of the resulting solid was washed with ethyl acetate (300 mL, 3.75 vol) and dried under vacuum to give 5-hydroxypentanamide (64.0 g, 68%) as a white solid. ¹H NMR δ(ppm): 7.20 (bs, 1H), 6.67 (bs, 1H), 4.36 (t, J=8.0 Hz, 1H); 3.39 (t, J=12 Hz, 2H), 1.53-1.47 (m, 2H), and 1.46-1.39 (m, 2H); FT-IR: 3400.56 cm⁻¹ (—OH, strong), 1643.3 cm⁻¹ (—C═O, amide), and 3183.57 cm⁻¹ (—N—H, amide), UPLC-ELSD: 99.84% purity (at 1.49 RT); MS: m/z=118.13[M+H]⁺.

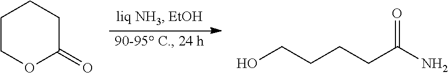 [SMILES: O=C1CCCCO1 ; "90-95° C., 24 h" ; "liq NH3, EtOH" ; NC(=O)CCCCO]

Synthesis of 5-Amino-5-oxopentyl methacrylate: A 250 mL 3-neck round bottom flask equipped with magnetic stir bar, internal thermometer, and nitrogen bubbler was charged with 5-hydroxypentanamide (5.0 g, 42.68 mmol) in dry dichloromethane (100 mL) at room temperature. N, N-dimethyl-4-aminopyridine (521 mg, 4.27 mmol) and triethylamine (11.9 mL, 85.36 mmol) were added thereto and the resulting suspension was stirred for 15 minutes. Methylacryloylchloride (5 mL, 51.21 mmol) was then added drop wise and the resulting mixture was stirred at room temperature for 16 h. The reaction product mixture was diluted with dichloromethane (100 mL) and washed with chilled water (100 mL) and a brine solution (50 mL). The organic layer was separated and dried over anhydrous sodium sulfate, filtered, and concentrated under reduced pressure. The crude material was triturated with 10% dichloromethane in hexanes to give 5-amino-5-oxopentyl methacrylate (6.0 g, 75%) as a pale-yellow solid. ¹H NMR δ(ppm): 7.25 (bs, 1H), 6.71 (bs, 1H), 6.02-6.01 (m, 1H), 5.67-5.66 (m, 1H); 4.13-4.07 (m, 2H), 1.88 (s, 3H), 1.64-1.57 (m, 4H); FT-IR: 2955.0 cm⁻¹ (—C═C—H stretch) 1649.17 cm⁻¹ (—C═O, amide), 1717.64 cm⁻¹ (—C═O, ester) and 3193.21 cm⁻¹ (—N—H, amide), LCMS-ELSD: 92.7% purity (at 1.40 RT); MS: m/z=186.23 [M+H]⁺.

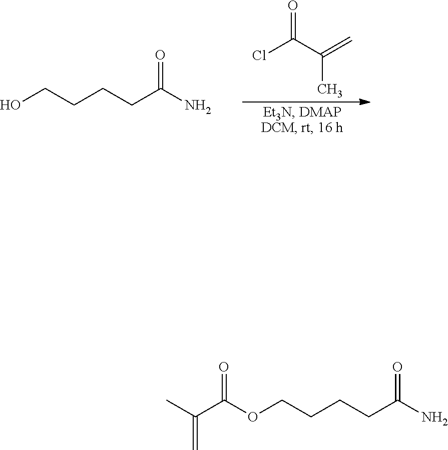

Synthesis of [5-[Bis(tert-butoxycarbonyl)amino]-5-oxo-pentyl] 2-methylprop-2-enoate (Monomer 13A): A 25 mL 3-neck round bottom flask equipped with magnetic stir bar and nitrogen bubbler was charged with 5-amino-5-oxopentyl methacrylate (200 mg, 1.08 mmol), N,N-dimethyl-4-aminopyridine (26.5 mg, 0.21 mmol), and acetonitrile (4 mL) at room temperature. (Boc)₂O (0.99 mL, 4.32 mmol) was added thereto and the resulting mixture was stirred at room temperature for 16 h, diluted with ethyl acetate (4 mL), and washed with water (2 mL) and brine (2 mL). The organic layer was separated and dried over anhydrous sodium sulfate, filtered, and concentrated under reduced pressure. The crude material was purified by flash column chromatography over silica gel (100-200 mesh) using an elution gradient of 0-3 vol % of ethyl acetate in hexanes to give [5-[bis(tert-butoxycarbonyl)amino]-5-oxo-pentyl] 2-methylprop-2-enoate (13, 50 mg, 12%) as a pale yellow liquid. ¹H NMR δ(ppm): 6.02 (t, J=1.6 Hz, 1H), 5.67 (t, J=3.2 Hz, 1H), 4.11 (t, J=12 Hz, 2H), 2.82 (t, J=14 Hz, 2H), 1.88 (s, 3H), 1.66-1.61 (m, 4H), 1.60 (s, 18H); FT-IR: 2982.9 cm⁻¹ (—C═C—H stretch), 1711.8 cm⁻¹ (—C═O, amide), 1787.0 cm⁻¹ (—C—C═O, ester); UPLC-ELSD: 99.55% purity (at 2.85 RT). No ionization was observed in either LCMS or GCMS. The structure of Monomer 13A was confirmed by 2D NMR.

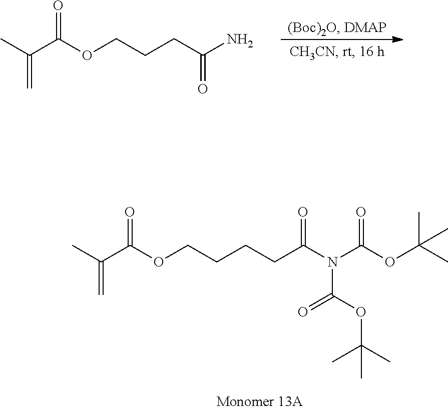

Synthesis of Monomer 17: The double-armed Monomer 17 is prepared as shown in Scheme 2:

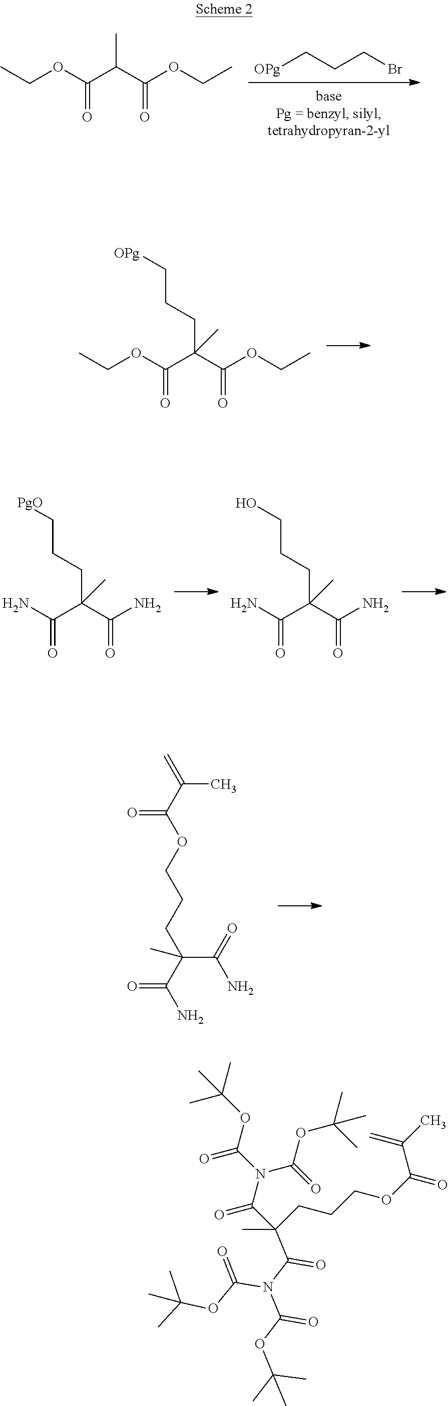

Polymer Synthesis: Exemplary polymer A2 is prepared as follows. A monomer feed solution is prepared using 23.4 g of propylene glycol monomethyl ether acetate (PGMEA), 10.0 g of Monomer 1, and 1.6 g of Monomer 4. Separately, an initiator feed solution is prepared using 8.3 g of PGMEA and 0.84 g of V-601. In a reactor, 9.4 g of PGMEA is warmed to 80° C., and then the monomer feed solution is added dropwise over 240 minutes, and the initiator feed solution is added dropwise over 90 minutes. After 4 hours, the reaction mixture is cooled to room temperature at 1° C./min, and then the polymer is precipitated by adding directly to 1 L of 9/1 methanol/water (v/v). The polymer is collected by filtration and dried in vacuo to give polymer A2.

Each of the polymers in Table 1 is prepared using a similar procedure and with a respective monomer feed solution. The amounts in Table 1 are mole percent (mol %) of repeating units derived from each specified monomer, based on the total moles of repeating units of the polymer.

TABLE 1

| | First | Second | Third | Fourth |
|---|---|---|---|---|
| Polymer | Monomer | Monomer | Monomer | Monomer |
| A1 | 1 (100%) | | | |
| A2 | 1 (80%) | 4 (20%) | | |
| A3 | 2 (100%) | | | |
| A4 | 2 (80%) | 5 (20%) | | |
| A5 | 13A (100%) | | | |
| A6 | 13A (90%) | 4 (10%) | | |
| B1 | 4 (40%) | 7 (30%) | 9 (20%) | 10 (10%) |
| B2 | 6 (40%) | 7 (40%) | 8 (20%) | |

The structures of monomers 1 to 10 and 13A are as follows:

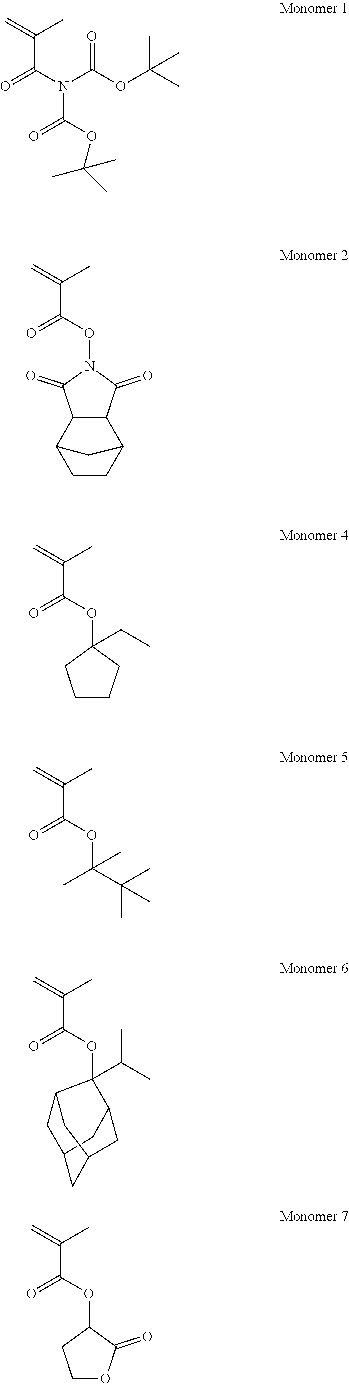

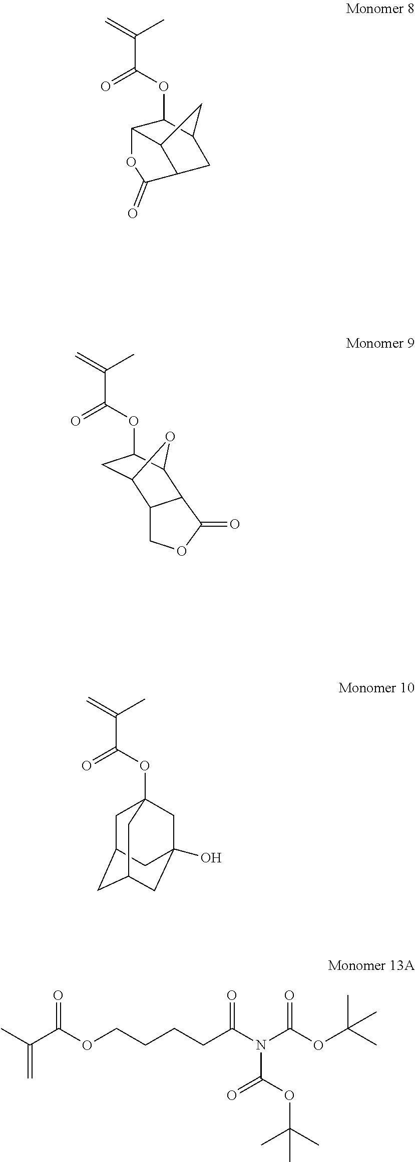 [SMILES: C=C(C)C(=O)OC1C2CC3C(=O)OC1C3C2 ; C=C(C)C(=O)OC1CC2OC1C1C(=O)OCC21 ; C=C(C)C(=O)OC12CC3CC(CC(O)(C3)C1)C2 ; C=C(C)C(=O)OCCCCC(=O)N(C(=O)OC(C)(C)C)C(=O)OC(C)(C)C]

The structures of photoactive compounds C1 and C2, and the quencher compounds D1 and D2 are shown below.

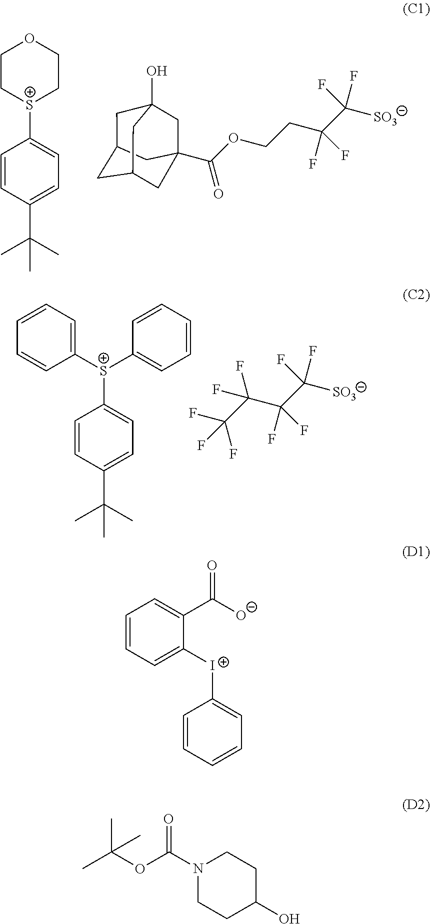

Photoresist Formulations. Photoresist compositions (R1-R6) are prepared by dissolving solid components in solvents using the materials and amounts set forth in Table 2. The resulting mixtures, made on a 14-30 g scale, are shaken on a mechanical shaker for from 3 to 24 hours and then filtered through a PTFE disk-shaped filter having a pore size of 0.2 μm. The amounts of Polymer 1, Polymer 2, PAG, quencher, and solvent are reported as wt % based on the total weight of the photoresist composition including solvents.

TABLE 2

| Photo- | | | | | |
|---|---|---|---|---|---|
| resist | | | | | |
| Compo- | Polymer | Polymer | | | |
| sition | 1 | 2 | PAG | Quencher | Solvents |
| R1 | B1 [2.27] | A1 [0.09] | C1 | D1 [0.11] | S1/S2 |
| | | | [0.53] | | [33.95/ |
| | | | | | 63.05] |
| R2 | B1 [2.27] | A2 [0.09] | C1 | D1 [0.11] | S1/S2 |
| | | | [0.53] | | [33.95/ |
| | | | | | 63.05] |
| R3 | B1 [2.27] | A3 [0.09] | C1 | D2 [0.11] | S1/S2 |
| | | | [0.53] | | [33.95/ |
| | | | | | 63.05] |
| R4 | B2 [2.27] | A4 [0.09] | C2 | D2 [0.11] | S1/S2 |
| | | | [0.53] | | [33.95/ |
| | | | | | 63.05] |
| R5 | B1 [2.27] | AS [0.09] | C1 | D1 [0.11] | S1/S2 |
| | | | [0.53] | | [33.95/ |
| | | | | | 63.05] |
| R6 | B2 [2.27] | A6 [0.09] | C1 | D1 [0.11] | S1/S2 |
| | | | [0.53] | | [33.95/ |
| | | | | | 63.05] |

Immersion Patterning. Immersion lithography is performed with a TEL Lithius 300 mm wafer track and ASML 1900i immersion scanner at 1.3 NA, 0.86/0.61 inner/outer sigma, and dipole illumination with 35Y polarization. Wafers for photolithographic testing are coated with an AR40A™ bottom antireflective coating (BARC) (DuPont Electronics & Imaging) and cured at 205° C. for 60 seconds to give an 800 Å film. A coating of AR104 BARC™ (DuPont Electronics & Imaging) is then disposed on the AR40A™ layer and cured at 175° C. for 60 seconds to give the top 400 Å film of the dual BARC stack. A photoresist composition is then coated onto the dual BARC stack and baked at 90° C. for 60 seconds to give a 900 Å resist film. Wafers are exposed targeting 55 nm/110 nm pitch and 43 nm/86 nm pitch 1:1 line/space (L/S) patterns using a focus exposure matrix and subjected to a PEB at 100° C. for 60 seconds. Following PEB, wafers are developed in 0.26 N TMAH solution for 12 seconds, rinsed with deionized water, and spun dry. Scanning electron microscopy (SEM) is performed to collect images and analyze printed patterns using a Hitachi CG4000 CD-SEM.

The inventive photoresist compositions R1-R6 are expected to achieve good patternability and lower defectivity.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photoresist composition, comprising:
a first polymer comprising a first repeating unit comprising an acid-labile group, and
a second polymer comprising a repeating unit derived from one or more monomers of formula (4);
a photoacid generator; and
a solvent, 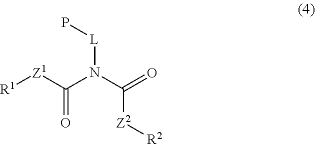
wherein, in formula (4),
Z¹ and Z² are each independently a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —N(R³)—, —S—, or —S(O)₂—, wherein R³ is hydrogen, substituted or unsubstituted C₁₋₂₀ alkyl, substituted or unsubstituted C₁₋₂₀ heteroalkyl, substituted or unsubstituted C₃₋₂₀ cycloalkyl, or substituted or unsubstituted C₂₋₂₀ heterocycloalkyl,
optionally, Z¹ and Z² together form a ring via a single bond or a double bond between Z¹ and Z²,
R¹ and R² are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, substituted or unsubstituted C₂₋₃₀ alkylheteroaryl, —OR⁴, or —N(R⁵)₂, wherein R⁴ and R⁵ are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl,
optionally, R¹ and R² together form a ring via a single bond or a divalent linking group,
L is a single bond or a multivalent linking group,
optionally, L is a multivalent linking group further comprising an additional group of the formula: 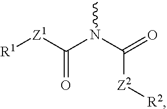
and
P is a polymerizable group.

2. The photoresist composition of claim 1, wherein the first repeating unit of the first polymer is derived from one or more monomers of formulae (1a), (1b), (1c), (1d), or (1e): 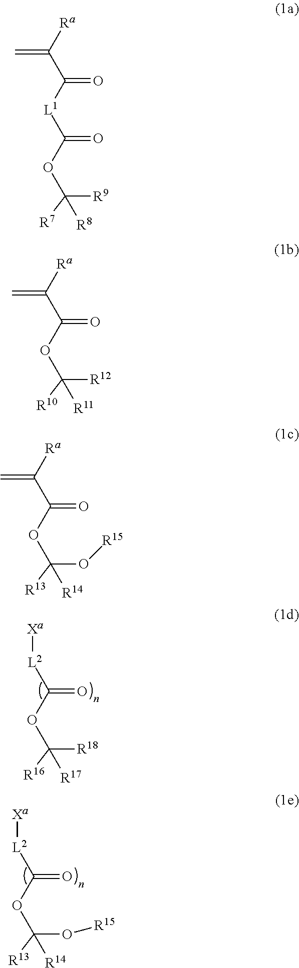
wherein,
R^{a} is hydrogen, fluorine, cyano, a substituted or unsubstituted C₁₋₁₀ alkyl, or a substituted or unsubstituted C₁₋₁₀ fluoroalkyl;
R⁷ to R¹² are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted;
provided that only one of R⁷ to R⁹ can be hydrogen and only one of R¹⁰ to R¹² can be hydrogen;
any two of R⁷ to R⁹ together optionally form a ring, and each of R⁷ to R⁹ optionally further comprises as part of their structure one or more groups selected from —O—, —C(O)—, —C(O)—O—, —S—, —S(O)₂—, and —N(R¹⁹)—S(O)₂—, wherein R¹⁹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
any two of R¹⁰ to R¹² together optionally form a ring, and each of R¹⁰ to R¹² optionally further comprises as part of their structure one or more groups selected from —O—, —C(O)—, —C(O)—O—, —S—, —S(O)₂—, and —N(R²⁰)—S(O)₂—, wherein R²⁰ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
L¹ is a divalent linking group comprising at least one carbon atom, at least one heteroatom, or a combination thereof;
R¹³ to R¹⁴ are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which except hydrogen is substituted or unsubstituted,
R¹⁵ is straight chain or branched C₁₋₂₀ alkyl, monocyclic or polycyclic C₃₋₂₀ cycloalkyl, or monocyclic or polycyclic C₂₋₂₀ heterocycloalkyl, each of which is substituted or unsubstituted, wherein one of R¹³ or R¹⁴ optionally forms a heterocyclic ring together with R¹⁵;
R¹⁶ to R¹⁸ are each independently straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted;
any two of R¹⁶ to R¹⁸ together optionally form a ring, and each of R¹⁶ to R¹⁸ optionally further comprises as part of their structure one or more groups selected from —O—, —C(O)—, —C(O)—O—, —S—, —S(O)₂—, and N(R²¹)—S(O)₂—, wherein R²¹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
X^{a} is a polymerizable group selected from norbornyl and vinyl;
n is 0 or 1; and
L² is a single bond or a divalent linking group, provided that L² is not a single bond when X^{a} is vinyl.

3. The photoresist composition of claim 1, wherein the first polymer further comprises a repeating unit derived from one or more monomers of formula (2): 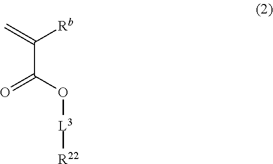
wherein,
R^{b} is hydrogen, fluorine, cyano, a substituted or unsubstituted C₁₋₁₀ alkyl, or a substituted or unsubstituted C₁₋₁₀ fluoroalkyl;
L³ is a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₇₋₃₀ arylalkylene, or substituted or unsubstituted C₁₋₃₀ heteroarylene, or substituted or unsubstituted C₂₋₃₀ heteroarylalkylene, wherein L³ optionally may further comprise one or more groups chosen from —O—, —C(O)—, —C(O)—O—, —S—, —S(O)₂—, and —N(R²³)—S(O)₂—, wherein R²³ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl; and
R²² is a monocyclic, polycyclic, or fused polycyclic C₄₋₂₀ lactone-containing group or a monocyclic, polycyclic, or fused polycyclic C₄₋₂₀ sultone-containing group.

4. The photoresist composition of claim 1, wherein the first polymer further comprises a repeating unit derived from one or more monomers of formula (3): 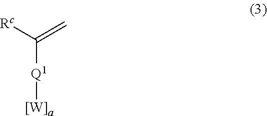
wherein,
R^{c} is hydrogen, fluorine, cyano, a substituted or unsubstituted C₁₋₁₀ alkyl, or a substituted or unsubstituted C₁₋₁₀ fluoroalkyl;
Q¹ is one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, or —C(O)—O—; and
W is a base-soluble group comprising —C(O)—OH; —C(CF₃)₂OH; an amide; an imide; or —NH—S(O)₂—Y¹ where Y¹ is F or C₁₋₄ perfluoroalkyl; and
a is an integer from 1 to 3.

5. The photoresist composition of claim 1, wherein the second polymer comprises a repeating unit derived from one or more monomers of formula (4a): 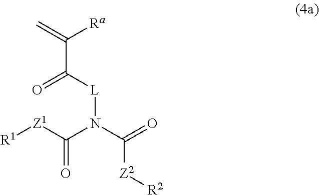
wherein,
R^{a} is hydrogen, fluorine, cyano, a substituted or unsubstituted C₁₋₁₀ alkyl, or a substituted or unsubstituted C₁₋₁₀ fluoroalkyl;
L is a single bond or a multivalent linking group;
optionally, L is a multivalent linking group further comprising an additional group of the formula: 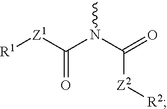
Z¹ and Z² are the same, wherein Z¹ and Z² are chosen from a single bond, —O—, a divalent linking group comprising a group of the formula —C(O)—, or a divalent linking group comprising a group of the formula —C(O)—O—;
R¹ and R² are each independently substituted or unsubstituted C₁₋₃₀ alkyl; and
optionally, R¹ and R² together form a ring via a single bond or a divalent linking group.

6. The photoresist composition of claim 1, wherein
L is a group of the formula —C(O)—C₁₋₁₀ alkylene-O—;
Z¹ and Z² are each —O—; and
R¹ and R² are each independently substituted or unsubstituted C₁₋₃₀ alkyl.

7. The photoresist composition of claim 1, wherein the photoacid generator is non-polymeric.

8. The photoresist composition of claim 1, further comprising a photo-decomposable quencher, a basic quencher, or a combination thereof.

9. The photoresist composition of claim 1, wherein a weight ratio of the first polymer to the second polymer is from 1:1 to 1,000:1.

10. A pattern formation method, comprising:
(a) applying a layer of the photoresist composition of claim 1 on a substrate;
(b) pattern-wise exposing the photoresist composition layer to activating radiation; and
(c) developing the exposed photoresist composition layer to provide a resist relief image.

11. The method of claim 10, wherein the first repeating unit of the first polymer is derived from one or more monomers of formulae (1a), (1b), (1c), (1d), or (1e): 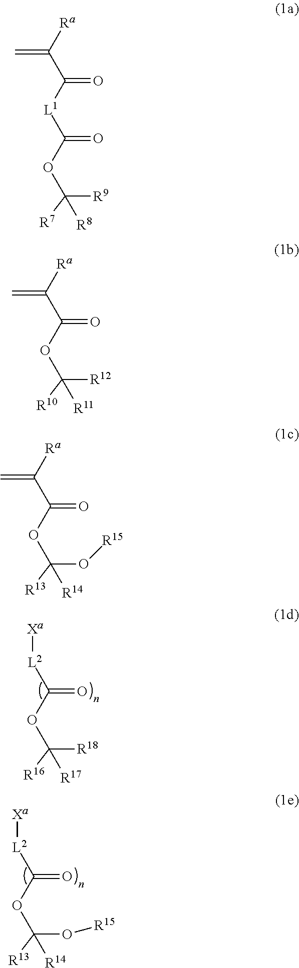
wherein,
R^{a} is hydrogen, fluorine, cyano, a substituted or unsubstituted C₁₋₁₀ alkyl, or a substituted or unsubstituted C₁₋₁₀ fluoroalkyl;
R⁷ to R¹² are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted;
provided that only one of R⁷ to R⁹ can be hydrogen and only one of R¹⁰ to R¹² can be hydrogen;
any two of R⁷ to R⁹ together optionally form a ring, and each of R⁷ to R⁹ optionally further comprises as part of their structure one or more groups selected from —O—, —C(O)—, —C(O)—O—, —S—, —S(O)₂—, and —N(R¹⁹)—S(O)₂—, wherein R¹⁹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
any two of R¹⁰ to R¹² together optionally form a ring, and each of R¹⁰ to R¹² optionally further comprises as part of their structure one or more groups selected from —O—, —C(O)—, —C(O)—O—, —S—, —S(O)₂—, and —N(R²⁰)—S(O)₂—, wherein R²⁰ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
L¹ is a divalent linking group comprising at least one carbon atom, at least one heteroatom, or a combination thereof;
R¹³ to R¹⁴ are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which except hydrogen is substituted or unsubstituted,
R¹⁵ is straight chain or branched C₁₋₂₀ alkyl, monocyclic or polycyclic C₃₋₂₀ cycloalkyl, or monocyclic or polycyclic C₂₋₂₀ heterocycloalkyl, each of which is substituted or unsubstituted, wherein one of R¹³ or R¹⁴ optionally forms a heterocyclic ring together with R¹⁵;
R¹⁶ to R¹⁸ are each independently straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted;
any two of R¹⁶ to R¹⁸ together optionally form a ring, and each of R¹⁶ to R¹⁸ optionally further comprises as part of their structure one or more groups selected from —O—, —C(O)—, —C(O)—O—, —S—, —S(O)₂—, and N(R²¹)—S(O)₂—, wherein R²¹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
X^{a} is a polymerizable group selected from norbornyl and vinyl;
n is 0 or 1; and
L² is a single bond or a divalent linking group, provided that L² is not a single bond when X^{a} is vinyl.

12. The method of claim 10, wherein the first polymer further comprises a repeating unit derived from one or more monomers of formula (2): 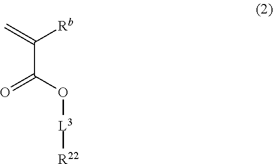
wherein,
R^{b} is hydrogen, fluorine, cyano, a substituted or unsubstituted C₁₋₁₀ alkyl, or a substituted or unsubstituted C₁₋₁₀ fluoroalkyl;
L³ is a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₇₋₃₀ arylalkylene, or substituted or unsubstituted C₁₋₃₀ heteroarylene, or substituted or unsubstituted C₂₋₃₀ heteroarylalkylene, wherein L³ optionally may further comprise one or more groups chosen from —O—, —C(O)—, —C(O)—O—, —S—, —S(O)₂—, and —N(R²³)—S(O)₂—, wherein R²³ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl; and
R²² is a monocyclic, polycyclic, or fused polycyclic C₄₋₂₀ lactone-containing group or a monocyclic, polycyclic, or fused polycyclic C₄₋₂₀ sultone-containing group.

13. The method of claim 10, wherein the first polymer further comprises a repeating unit derived from one or more monomers of formula (3): 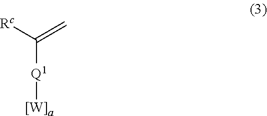
wherein,
R^{c} is hydrogen, fluorine, cyano, a substituted or unsubstituted C₁₋₁₀ alkyl, or a substituted or unsubstituted C₁₋₁₀ fluoroalkyl;
Q¹ is one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, or —C(O)—O—; and
W is a base-soluble group comprising —C(O)—OH; —C(CF₃)₂OH; an amide; an imide; or —NH—S(O)₂—Y¹ where Y¹ is F or C₁₋₄ perfluoroalkyl; and
a is an integer from 1 to 3.

14. The method of claim 10, wherein the second polymer comprises a repeating unit derived from one or more monomers of formula (4a): 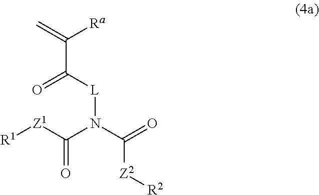
wherein,
R^{a} is hydrogen, fluorine, cyano, a substituted or unsubstituted C₁₋₁₀ alkyl, or a substituted or unsubstituted C₁₋₁₀ fluoroalkyl;
L is a single bond or a multivalent linking group;
optionally, L is a multivalent linking group further comprising an additional group of the formula: 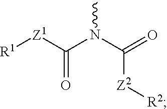
Z¹ and Z² are the same, wherein Z¹ and Z² are chosen from a single bond, —O—, a divalent linking group comprising a group of the formula —C(O)—, or a divalent linking group comprising a group of the formula —C(O)—O—;
R¹ and R² are each independently substituted or unsubstituted C₁₋₃₀ alkyl; and
optionally, R¹ and R² together form a ring via a single bond or a divalent linking group.

15. The method of claim 10, wherein
L is a group of the formula —C(O)—C₁₋₁₀ alkylene-O—;
Z¹ and Z² are each —O—; and
R¹ and R² are each independently substituted or unsubstituted C₁₋₃₀ alkyl.

16. The method of claim 10, wherein the photoacid generator is non-polymeric.

17. The method of claim 10, further comprising a photo-decomposable quencher, a basic quencher, or a combination thereof.

18. The method of claim 10, wherein a weight ratio of the first polymer to the second polymer is from 1:1 to 1,000:1.
